(19) United States
(12) Patent Application Publication
(10) Pub. No.: US 2013/0258259 A1
(43) Pub. Date: Oct. 3, 2013

(54) COLOR FILTER, SOLID-STATE IMAGING ELEMENT, LIQUID CRYSTAL DISPLAY APPARATUS AND ELECTRONIC INFORMATION DEVICE

(71) Applicant: Junichi Nakai, Osaka-shi (JP)

(72) Inventor: Junichi Nakai, Osaka-shi (JP)

(73) Assignee: SHARP KABUSHIKI KAISHA, Osaka-shi, Osaka (JP)

(21) Appl. No.: 13/992,471

(22) PCT Filed: Dec. 6, 2011
(86) PCT No.: PCT/JP2011/006820

§ 371 Date: Jun. 7, 2013

(30) Foreign Application Priority Data
Dec. 9, 2010 (JP) 2010-275151
Jan. 24, 2011 (JP) 2011-012408

(51) Int. Cl. H04N 5/357; G02F 1/1335; G02B 5/23

(52) U.S. Cl. CPC H04N 5/357; G02B 5/23; G02F 1/133514
USPC 349/106; 359/891; 250/208.1

(57) ABSTRACT

Color reproduction is improved by reducing color noise without changing color signal processing of a device in such a manner to match a new color filter arrangement. The film thickness of a green (G) color layer in a Bayer color arrangement is made thin to be the green (G) color layer having a steeply inclined spectral characteristic with a high range of transmissivity extended towards the short wavelength, and a yellow (Y1) color layer with a thin film thickness is newly stacked on the thinned green (G1) color layer. Thereby the y-axis value of the spectral characteristic of green (G) of the green (G) color layer becomes greater than or equal to 0.45 and less than or equal to 0.60 on a CIE chromaticity diagram.

### TECHNICAL FIELD

The present invention relates to color filters in which the three primary colors RGB are arranged in a predetermined color arrangement; a solid-state imaging element for photo-electrically converting and capturing an image from the image light of a subject using the color filter; a liquid crystal display apparatus for displaying an image using the color filter; and an electronic information device, such as a digital camera (e.g., a digital video camera or a digital still camera), an image input camera (e.g., a monitoring camera), a scanner, a facsimile machine, a videophone, or a camera-equipped cell phone device, using the solid-state imaging apparatus in an imaging section as an image input device, and/or using the liquid crystal display apparatus as a display section.

### BACKGROUND ART

An example of a color arrangement of R, G, and B of color filters used for this type of conventional solid-state imaging element being a Bayer color arrangement will be described with reference to FIGS. 10 and 11.

FIG. 10 is a block diagram schematically showing an example of a configuration of an essential part of a conventional solid-state imaging apparatus disclosed in Patent Literature 1.

In FIG. 10, pixels 101 having sensitivity to a wavelength range corresponding to the three primary colors of light (R: red, G: green, and B: blue) are arranged in a two dimensional matrix pattern in a conventional solid-state imaging apparatus 100, and a vertical shift register 102 and a horizontal shift register 103 for scanning are arranged in the periphery thereof. The vertical shift register 102 and the horizontal shift register 103 are readout circuits for reading out pixel signals from each pixel 101 of a solid-state imaging element. As an example, a decoder may also be used as a readout circuit.

The conventional solid-state imaging apparatus 100 also comprises a pixel power supply section 104, a drive section 105, a signal summation circuit 106, and an output amplifier 107. The pixel power supply section 104 supplies voltage to be applied in order to read out pixel signals from each pixel. The drive section 105 controls the operation of the vertical shift register 102, the horizontal shift register 103, and the signal summation circuit 106. The signal summation circuit 106 sums up pixel signals of a plurality of pixels and outputs a resulting signal. This processing is spatial summation processing represented by what is known as binning processing.

FIG. 11 is a spectrum diagram showing a photoelectric conversion characteristic of each pixel 101 of R, G, and B in FIG. 10. As shown by a solid line in FIG. 11, each of the R pixel spectrum, G pixel spectrum, and B pixel spectrum has a peak value at a wavelength in the vicinity of 620 nm, 550 nm, and 470 nm, respectively.

Next, an example of a color arrangement with a pixel of Y (yellow) added to each pixel arrangement of R, G, and B, by which an improvement in color reproduction and high sensitivity is attempted, will be described in detail with reference to Patent Literature 2.

FIG. 12 is a plane view showing a pixel arrangement of a conventional solid-state imaging element disclosed in Patent Literature 2.

As shown in FIG. 12, from the four colors as green (G′), yellow (Y), red (R′), and blue (B) of a color filter, a spectral characteristic of a color filter of RGB primary colors can be obtained by computational processing from computational formulas R=R′×Y, G=G′×Y, and B=B. In this manner, an individual color filter of pixels is made thinner by providing a separate pixel of yellow (Y) from a common pigment component.

Next, an example of an attempt to improve color reproduction and high sensitivity with a four color arrangement of R, G1, B, and G2 will be described in detail with reference to Patent Literature 3.

FIG. 13(a) is a plane view schematically showing a plane color arrangement of color filters in a conventional solid-state imaging element disclosed in Patent Literature 3 in a smallest repeating unit. FIG. 13(b) is a longitudinal cross-sectional view of a conventional solid-state imaging element containing color filters in the direction of the line X-X′ in FIG. 13(a). FIG. 13(c) is a longitudinal cross-sectional view of color filters in the direction of the line X-X′ in FIG. 13(a).

As shown in FIG. 13(a), a first green (G1) color layer and a second green (G2) color layer are placed in their own respective sections where G (green) color layers are placed on two diagonally opposing locations in a conventional Bayer arrangement. Specifically, different color layers, the first green (G1) color layer and the second green (G2) color layer, are placed on sections where color layers of the same single green color are placed conventionally.

As shown in FIG. 13(b), a conventional solid-state imaging element 300 primarily has a semiconductor circuit board 302 having a plurality of photoelectric conversion elements 301; a color filter 303 formed above the semiconductor circuit board 302; and microlenses 304 formed above the color filter 303. The color filter 303 has a plurality of color layers in a predetermined color arrangement such that a color layer corresponds to each individual photoelectric conversion element 301 provided in the semiconductor circuit board 302. Each light gathering microlens 304 is placed to correspond to each photoelectric conversion element 301 above the color filter 303 to gather and take in incident light from the outside to the photoelectric conversion element 301. Further, transparent planarizing layers 305 and 306 are provided to planarize and improve the shape of the underlying surfaces of the color filter 303 and the microlenses 304, respectively.

As shown in FIG. 13(c), the G2 (green 2) color layer has a lamination configuration, and includes a color layer of the same color as the G1 (green 1) layer 311 in the lamination configuration. Specifically, a lowest layer 311′ of the G2 color layer has the same color layer as the G1 (green 1) layer 311. In the G2 color layer, it is preferred that the pixel size of a top layer 312 laminated on the lowest layer 311′ constituting the G2 layer is made smaller than the pixel size of the lowest layer 311′. This is to facilitate overlaying (to make it easily overlap) the pixel edge (edge part) of adjacent pixels, such as an R layer 313 and a B layer 314, onto the pixel edge (edge part) of the G1 layer 311 and the bottom layer 311 of the G2 layer. Pixel peeling, which tends to occur when the pixel size is small, can be prevented by overlaying the edges of the R layer 313 and the B layer 314, which are thick layers, over the edges of the G1 layer 311 and the lowest layer 311′, which are comparatively thin layers.

Next, an example of an attempt to improve color reproduction and high sensitivity by adding a color arrangement of complimentary colors YMC to a color arrangement of the primary colors RGB will be described in detail with reference to Patent Literature 4 and 5.

FIG. 14 is a plane view schematically showing a plane color arrangement of color filters in a conventional solid-state imaging element disclosed in Patent Literatures 4 and 5.

In FIG. 14, a conventional solid-state imaging element 400 comprises pixels 401, which are configured by combining a primary light sensitive section 402 having a light sensor with sufficient area to obtain incident light at high sensitivity, and an auxiliary light sensitive section 403 having a light sensor with area smaller than the primary light sensitive section 402 to obtain incident light at low sensitivity. A primary color filter 404 and a complimentary color filter 405 are provided to the primary light sensitive section 402 and the auxiliary light sensitive section 403, respectively, and the light sensitive sections 402 and 403 output primary imaging signals and auxiliary imaging signals, respectively, thereby realizing an image with high sensitivity and color reproduction, and a light gathering auxiliary microlens 406 in the auxiliary light sensitive section 403 is formed to be small. The reference numeral 407 denotes a light gathering primary microlens corresponding to the primary color filter 404.

### CITATION LIST

### Patent Literature

Patent Reference 1: Japanese Laid-Open Publication No. 2010-183357
Patent Reference 2: Japanese Laid-Open Publication No. 2007-27610
Patent Reference 3: Japanese Laid-Open Publication No. 2010-78970
Patent Reference 4: Japanese Laid-Open Publication No. 2006-270356
Patent Reference 5: Japanese Laid-Open Publication No. 2006-270364

### SUMMARY OF THE INVENTION

### Technical Problem

The conventional solid-state imaging element disclosed in Patent Literature 1 merely shows an example of the color arrangement of R, G, and B of the color filters in the Bayer color arrangement. In the conventional solid-state imaging elements disclosed in Patent Literatures 2 to 5, the color arrangement of R, G, and B of color filters is altered by increasing the color variety of the Bayer color arrangement for each pixel to improve color reproduction and high sensitivity.

However, in each conventional solid-state imaging element described above, if the number of colors used for the color arrangement for a plurality of pixels is increased from that of the Bayer color arrangement, then color signal processing of a device must be initially changed to match a new color filter arrangement from scratch, which poses the problem of complicating adjustment of color signal processing.

The present invention is intended to solve the conventional problem described above. An objective of the present invention is to provide: color filters capable of improving color reproduction by reducing color noise without changing color signal processing of a device to match a new color filter arrangement; a solid-state imaging element capable of improving color reproduction and high sensitivity using the color filters; a liquid crystal display apparatus capable of improving color reproduction and high sensitivity using the color filters; and an electronic information device, such as a camera-equipped cell phone, using the solid-state imaging element in an imaging section as an image input device, and/or using the liquid crystal display apparatus in a display section.

### Solution to Problem

Color filters of the three primary colors according to the present invention includes a red (R) color layer, a green (G) color layer, and a blue (B) color layer in a predetermined color arrangement in a plane view, where a spectral characteristic of green (G) of the green (G) color layer has a y-axis value greater than or equal to 0.45 and less than or equal to 0.60 on a CIE chromaticity diagram, thereby achieving the objective described above.

Preferably, in color filters according to the present invention, the transmittance to an optical wavelength at the spectral characteristic of green (G) of the green (G) color layer is greater than 0 percent and less than or equal to 20 percent at an optical wavelength of 450 nm.

Still preferably, in color filters according to the present invention, the transmittance to an optical wavelength at the spectral characteristic of green (G) of the green (G) color layer is greater than 0 percent and less than or equal to 10 percent at an optical wavelength of 450 nm.

Still preferably, in color filters according to the present invention, the transmittance to an optical wavelength at the spectral characteristic of green (G) of the green (G) color layer is greater than or equal to 60 percent and less than or equal to 98 percent at an optical wavelength of 500 nm.

Still preferably, in color filters according to the present invention, the transmittance to an optical wavelength at the spectral characteristic of green (G) of the green (G) color layer is greater than or equal to 60 percent and less than or equal to 90 percent at an optical wavelength of 500 nm.

Still preferably, in color filters according to the present invention, the transmittance to an optical wavelength at the spectral characteristic of green (G) of the green (G) color layer is greater than 0 percent and less than or equal to 30 percent at an optical wavelength of 650 nm.

Still preferably, in color filters according to the present invention, the transmittance to an optical wavelength at the spectral characteristic of green (G) of the green (G) color layer is greater than 0 percent and less than or equal to 20 percent at an optical wavelength of 650 nm.

Still preferably, in color filters according to the present invention, the green (G) color layer is a two-layer configuration of a green (G1) color layer having a steeply inclined spectral characteristic with a high range of transmissivity extended towards the short wavelength and a yellow (Y1) color layer.

Still preferably, in color filters according to the present invention, layer thicknesses of the green (G1) color layer and the yellow (Y1) color layer are thinner compared to layer thicknesses of the red (R) color layer and the blue (B) color layer excluding the green (G) color layer.

Still preferably, in color filters according to the present invention, the layer thickness of the two-layer configuration of the green (G1) color layer and the yellow (Y1) color layer is substantially the same as the layer thicknesses of the red (R) color layer or the blue (B) color layer excluding the green (G) color layer.

Still preferably, in color filters according to the present invention, the layer thickness of the green (G1) color layer and the layer thickness of the yellow (Y1) color layer are substantially the same.

Still preferably, in color filters according to the present invention, the green (G) color layer is divided into two regions in the plane view; one of the divided regions is constituted of a green (G2) color layer having a steeply inclined spectral characteristic with a high range of transmissivity extended towards the short wavelength; and the other one of the divided regions is constituted of a yellow (Y2) color layer.

Still preferably, in color filters according to the present invention, areas of respective regions of the green (G2) color layer and the yellow (Y2) color layer are substantially the same.

Still preferably, in color filters according to the present invention, the arrangement of the green (G2) color layer and the yellow (Y2) color layer is such that the green (G2) color layer and the yellow (Y2) color layer are arranged in an alternating order for each minimum repeating adjacent four-pixel unit in a Bayer color arrangement.

Still preferably, in color filters according to the present invention, green (G) color material and yellow (Y) color material are mixed into clear base material, thereby giving the green (G) color layer a steeply inclined spectral characteristic with a high range of transmissivity extended towards the short wavelength.

Still preferably, in color filters according to the present invention, green (G) color material and yellow (Y) color material are mixed into clear base material, thereby giving the green (G) color layer a steeply inclined spectral characteristic with a high range of transmissivity extended towards the short wavelength and layer thickness substantially the same as the layer thickness of the red (R) color layer or the blue (B) color layer excluding the green (G) color layer.

Still preferably, in color filters according to the present invention, the predetermined color arrangement is a Bayer color arrangement.

Still preferably, in color filters according to the present invention, at least one of the green (G) color layer, the green (G1) color layer, and the green (G2) color layer has a steeply inclined spectral characteristic with a high range of transmissivity extended towards the short wavelength in comparison to a conventional green (G) color layer.

Still preferably, in color filters according to the present invention, the ratio of the area in which the spectral characteristic of green (G) overlaps with the spectral characteristic of blue (B) is 23 percent±10 percent, and the ratio of the area in which the spectral characteristic of green (G) overlaps with the spectral characteristic of red (R) is 18 percent±5 percent.

A solid-state imaging element according to the present invention, with a plurality of light reception sections arranged in a two dimensional pattern for photo-electrically converting and capturing an image of an image light from a subject, is provided, where color filters according to the present invention are formed in such a manner as to match each of the plurality of light reception sections for respective colors, thereby achieving the objective described above.

Preferably, in a solid-state imaging element according to the present invention, the solid-state imaging element is a CCD solid-state imaging element or a CMOS solid-state imaging element.

A liquid crystal display apparatus according to the present invention is provided, in which liquid crystal is held between an element side substrate and an opposing side substrate, and an image is displayed according to the light transmittance of liquid crystal for each pixel, where color filters according to the present invention are formed on the opposing side substrate in such a manner to match each pixel for each color, thereby achieving the objective described above.

An electronic information device according to the present invention, using the solid-state imaging element according to the present invention in an imaging section as an image input device, is provided, thereby achieving the objective described above.

An electronic information device according to the present invention, using the liquid crystal display apparatus according to the present invention in a display section, is provided, thereby achieving the objective described above.

Hereinafter, an effect of the present invention in the configuration described above will be described.

In the present invention, a spectral characteristic of green (G) of the green (G) color layer has a y-axis value greater than or equal to 0.45 and less than or equal to 0.60 on a CIE chromaticity diagram in color filters where a red (R) color layer, a green (G) color layer, and a blue (B) color layer of the three primary colors are arranged in a predetermined color arrangement in a plane view.

Thus, when the spectral characteristic of green (G) of the green (G) color layer has a y-axis value greater than or equal to 0.45 and less than or equal to 0.60 on the CIE chromaticity diagram by making the thickness of a green film in a Bayer color arrangement thinner and adding a new thin yellow film thereon, color noise can be reduced and color reproduction can be improved, without changing the color signal processing of a device in such a manner to match the new color filter color arrangement.

Manufacturing steps of color filters become complicated and the manufacturing time increases by making the thickness of a green film in a Bayer color arrangement thinner and adding a new thin yellow film thereon. However, when color filters are formed by adding yellow to green in a Bayer color arrangement to make a new green, such manufacturing steps of color filters will not become complicated and improvement in color reproduction can be realized at low cost.

### Advantageous Effects of Invention

From the above description, according to the present invention, since the width of a green film in a Bayer color arrangement is made thinner and a new thin yellow film is added thereon, color noise can be reduced to improve color reproduction without changing color signal processing of a device to match a new color filter arrangement.

Also, color filters are formed by adding a yellow to a green of a Bayer color arrangement as a new green, thereby improvement of color reproduction can be realized at low cost without complicating manufacturing steps of color filters.

### BRIEF DESCRIPTION OF THE DRAWINGS

FIG. 1 is a longitudinal cross-sectional view schematically showing an example of a configuration of an essential part of a CCD solid-state imaging element according to Embodiment 1 of the present invention.

FIG. 2 (a) is a plane view schematically showing the color arrangement of the color filters in FIG. 1 in the smallest repeating unit. FIG. 2(b) is a longitudinal cross-sectional view of color filters in the direction of the line A-A′ in FIG. 2(a). FIG. 2(c) is a longitudinal cross-sectional view schematically showing an example of a variation of the color filter cross-sectional configuration in FIG. 2(b). FIG. 2(d) is a longitudinal cross-sectional view schematically showing another example of a variation of the color filter cross-sectional configuration in FIG. 2(b).

FIG. 3 is a spectral characteristic diagram showing the relationship between transmittance and optical wavelength of the green (G) color layer of the color filter in FIG. 1.

FIG. 4 is a diagram showing the relationship between three primary colors RGB of the conventional color filter and three primary colors RGB of the color filter of the present invention on a CIE chromaticity diagram.

FIG. 5 is an electric spectral characteristic diagram of three primary colors RGB of the color filter in Embodiment 1 of a device and three primary colors RGB of the conventional color filter of a device when the peak value of the electric output of the green (G) of the conventional color filter indicated by a dotted line is set to be 100 percent.

FIG. 6 is a partial plane view showing another example of the color arrangement of color filters in FIG. 1.

FIG. 7 is a longitudinal cross-sectional view schematically showing an example of a configuration of an essential part of the CMOS solid-state imaging element according to Embodiment 2 of the present invention.

FIG. 8(a) is a plane view schematically showing a minimum repeating unit of the color arrangement of the color filters in FIG. 7, and FIG. 8(b) is a longitudinal cross-sectional view of the color filters in a direction of a line B-B′ in FIG. 8(a).

FIG. 9 is a block diagram showing, as Embodiment 4 of the present invention, an example of a schematic configuration of an electronic information device using the solid-state imaging element 1, 1A, or 1B of Embodiments 1-3 of the present invention for an imaging section.

FIG. 10 is a block diagram schematically showing an example of a configuration of an essential part of a conventional solid-state imaging apparatus disclosed in Patent Literature 1.

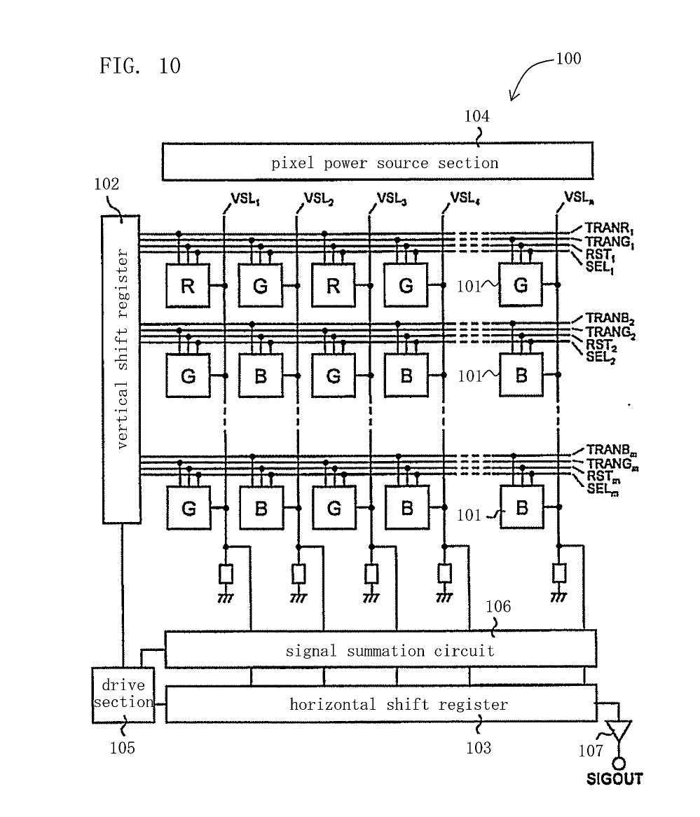

FIG. 11 is a spectrum diagram showing a photoelectric conversion characteristic of each pixel of R, G, and B in FIG. 10.

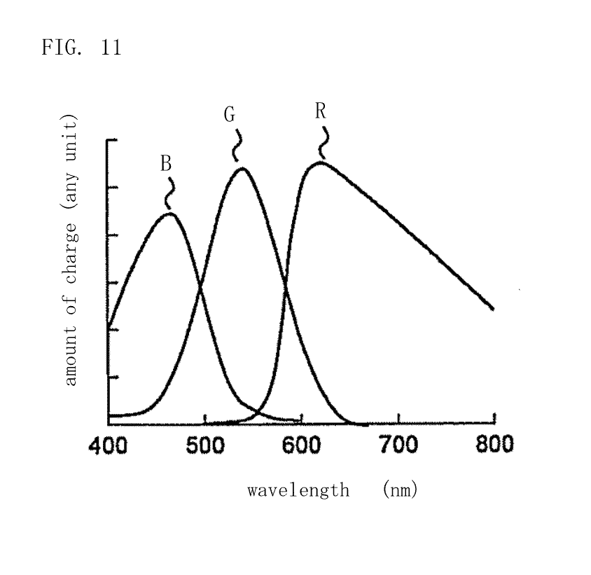

FIG. 12 is a plane view showing a pixel arrangement of a conventional solid-state imaging element disclosed in Patent Literature 2.

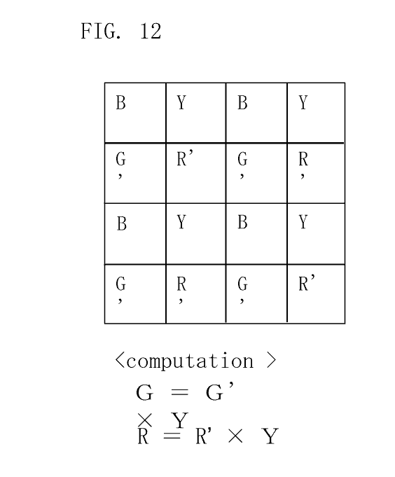

FIG. 13(a) is a plane view schematically showing a plane color arrangement of color filters in a conventional solid-state imaging element disclosed in Patent Literature 3 in a smallest repeating unit. FIG. 13(b) is a longitudinal cross-sectional view of a conventional solid-state imaging element containing color filters in the direction of the line X-X′ in FIG. 13(a). FIG. 13(c) is a longitudinal cross-sectional view of color filters in the direction of the line X-X′ in FIG. 13(a).

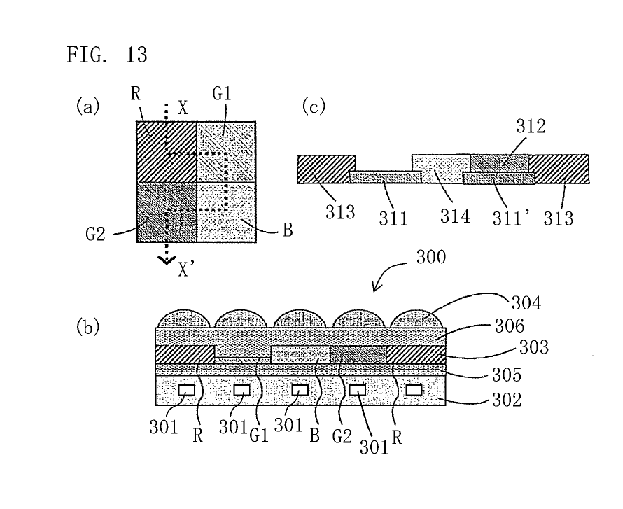

FIG. 14 is a plane view schematically showing a plane color arrangement of color filters in a conventional solid-state imaging element disclosed in Patent Literatures 4 and 5.

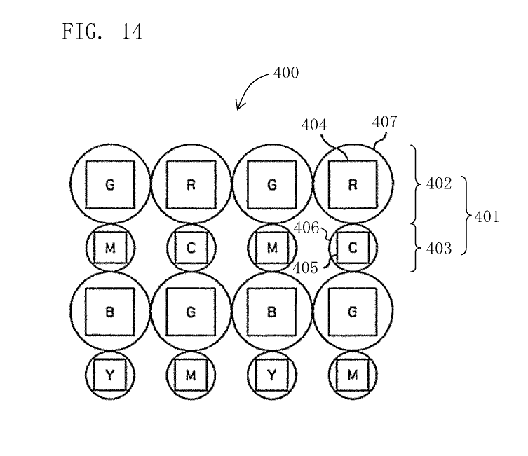

FIG. 15 is a longitudinal cross-sectional diagram schematically showing an example of a configuration of an essential part of a CCD solid-state imaging element in Embodiment 3 of the present invention.

FIG. 16 is a spectral characteristic diagram showing the relationship between transmittance and optical wavelength of the green (G) color layer of the color filter 17G in FIG. 15.

FIG. 17 is an electric spectral characteristic diagram of three primary colors RGB of the color filter in Embodiment 3 of a device and three primary colors RGB of the conventional color filter of a device when the peak value of the electrical output of the green (G) of the conventional color filter indicated by a dotted line is set to be 100 percent.

### REFERENCE SIGNS LIST

1, 1B CCD solid-state imaging element
2 semiconductor substrate
3 light reception section
4 charge transfer section
5 gate insulation film
6 gate electrode
7 pixel section
8 stop layer
9 light shield film
9a opening section
10 insulation film
11 interlayer insulation film
12 inner-layer lens
13 interlayer insulation film
14, 14R, 14G (14G1+14Y1), 14B color filters
15 planarizing film
16 microlens
17R, 17G, 17B color filters
1A CMOS solid-state imaging element
21 semiconductor substrate
22 light reception section
23 charge transfer section
24 transfer gate
25 gate insulation film
26 logic transistor region
27 pixel region
28 interlayer insulation film
29 first wiring layer
30 interlayer insulation film
31 second wiring layer
32, 33 contact plugs
34 interlayer insulation film
35 R, G•Y, B color filters
36 planarizing film
37 microlens
90 electronic information device
91 solid-state imaging apparatus
92 memory section
93 display section
94 communication section
95 image output section

### DESCRIPTION OF EMBODIMENTS

Hereinafter, Embodiments 1 to 4 of the present invention will be described in detail with reference to the accompanying figures. Embodiments 1 to 3 will describe a solid-state imaging element with color filters of the present invention applied thereto. Embodiment 4 will describe an electronic information device, such as a camera-equipped cell phone, using any one of Embodiments 1 to 3 of the solid-state imaging element in an imaging section as an image input device. In view of preparing the figures, thicknesses, lengths or the like of the elements in the figures are not limited to those described in the figures.

### Embodiment 1

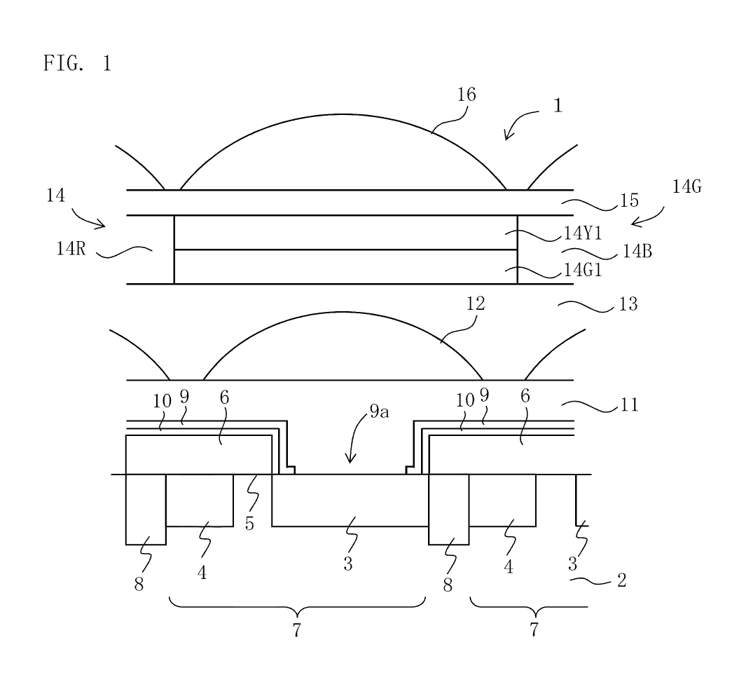

FIG. 1 is a longitudinal cross-sectional view schematically showing an example of a configuration of an essential part of a CCD solid-state imaging element according to Embodiment 1 of the present invention.

In FIG. 1, a plurality of pixel sections are arranged in a two dimensional matrix pattern in rows and columns in a CCD solid-state imaging element 1 according to Embodiment 1. In each pixel section thereof, a light reception section 3 is provided as a light reception element which is configured with a photodiode that photo-electrically converts incident light to produce signal charges, on a surface section of a semiconductor substrate 2. Adjacent the light reception section 3, a charge transfer section 4 is provided for reading out signal charges from the light reception section 3 via a signal charge read-out section and for transferring the charges. A gate electrode 6 is placed above the charge transfer section 4 and the signal charge read-out section with a gate insulation film 5 interposed therebetween. The gate electrode 6 not only reads out signal charges, but also functions as a charge transfer electrode for regulating charge transfers of signal charges that are read out. A channel stop layer 8 is provided as a pixel separation layer (an element separation layer) in between pixel sections 7 (in the horizontal direction) of a semiconductor substrate 2 consisting of the light reception section 3 and the charge transfer section 4.

Above the gate electrode 6, a light shield film 9 is formed with an insulation film 10 interposed therebetween to prevent noise from occurring due to reflection of incident light by the gate electrode 6. An opening section 9a is also formed as a window section for incident light on the light shield film 9 above the light reception section 3.

An interlayer insulation film 11 is formed for planarizing a section with difference in height between the surface of the light reception section 3 and the shield film 9. Inner-layer lens 12 for gathering light to the light reception section 3 is formed on the interlayer insulation film 11, with each inner-layer lens 12 corresponding to a single light reception section 3. An interlayer insulation film 13 is formed on each inner-layer lens 12 for filling in the difference in height in between each inner-layer lens 12 to planarize the surfaces thereof.

Further, color filters 14 (14R, 14G (14G1+14Y1), 14B) with a predetermined color arrangement (for example a Bayer arrangement) of each color R, G, and B placed at each light reception section 3 is formed on the interlayer insulation film 13. Further, a planarizing film 15 is formed on the color filters 14 and a microlens 16 for gathering light to the light reception section 3 is additionally formed thereon.

In this case, each of the color filters 14R and 14B has a film thickness substantially the same as that of the color filter 14G1+14Y1 consisting of two layers. Further, the film thickness of the color filter 14G is also substantially the same as that of the color filter 14Y.

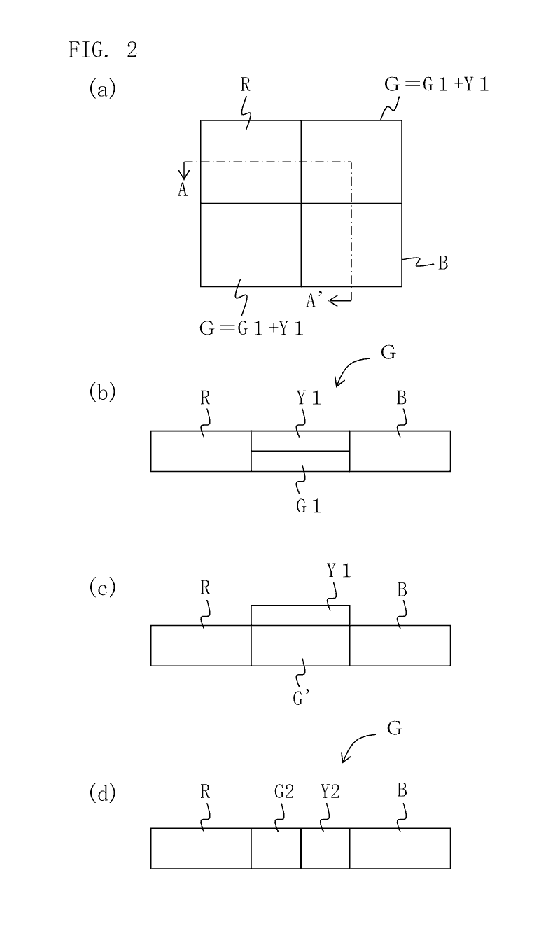

FIG. 2 (a) is a plane view schematically showing the color arrangement of the color filters 14 in FIG. 1 in the smallest repeating unit. FIG. 2(b) is a longitudinal cross-sectional view of color filters in the direction of the line A-A′ in FIG. 2 (a). FIG. 2(c) is a longitudinal cross-sectional view schematically showing an example of a variation of the color filter cross-sectional configuration in FIG. 2(b). FIG. 2(d) is a longitudinal cross-sectional view schematically showing another example of a variation of the color filter cross-sectional configuration in FIG. 2(b).

In FIG. 2(a), the color filters 14 consisting of three primary colors RGB in the Bayer color arrangement are shown in the smallest repeating unit. An R (red) color layer of the color filter 14R and a B (blue) color layer of the color filter 14B are arranged diagonally in a plane view, and color filters 14G (G1+Y1) are each arranged in the opposite diagonal direction. In FIG. 2(b), in between a longitudinal cross-sectional configuration of the R (red) color layer of the color filter 14R and the B (blue) color layer of the color filter 14B is placed a pixel of a two-layer top-and-bottom configuration with a G1 (green) color layer (a thin bottom layer) of the color filter 14G and a Y1 (yellow) color layer (thin top layer) of the color filter 14Y. The G1 (green) color layer of the color filter 14G and the Y1 (yellow) color layer of the color filter 14Y may be positioned in a reverse order (top layer on the bottom).

Specifically, a green (G) color layer of the color filter 14G has a two-layer configuration consisting of the green (G1) color layer with thinner layer thickness compared to the film thickness of layer regions other than the green (G) color layer, and yellow (Y1) color layer with a thinner layer thickness compared to the thickness of the layer regions other than the green (G) layer. The layer thickness of the two-layer configuration consisting of the green (G1) color layer and the yellow (Y1) color layer is substantially the same as that of color layers other than the green (G) color layer, namely the red (R) color layer or the blue (B) color layer. Also, respective layer thicknesses of the green (G1) color layer and the yellow (Y1) color layer are substantially the same as each other.

Longitudinal cross-sectional configurations of the color filters of FIG. 2(c) and FIG. 2(d) will be discussed below in greater detail.

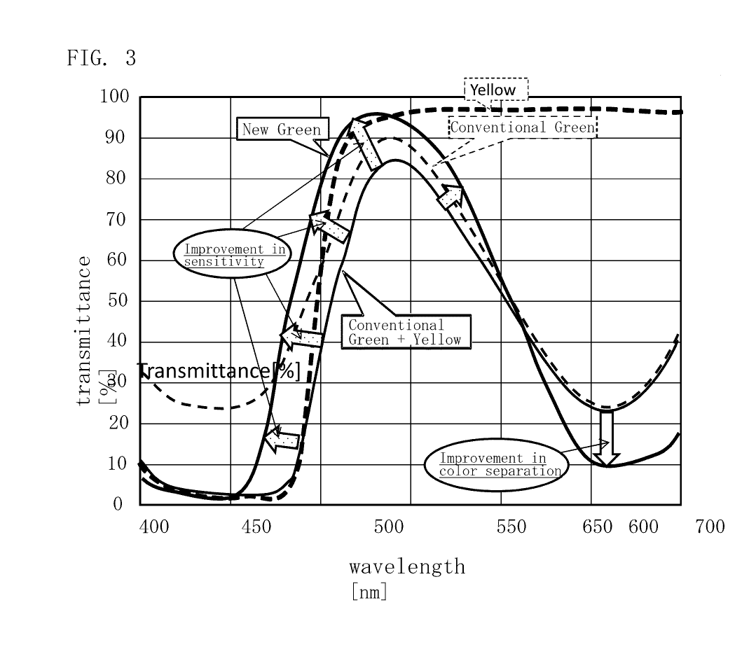

FIG. 3 is a spectral characteristic diagram showing the relationship between transmittance and optical wavelength of the green (G) color layer of the color filter 14G in FIG. 1.

As shown in FIG. 3, the spectral characteristic of the yellow (Y1) indicated by a thick dotted line as “Yellow” is obtained by processing signals using the spectral characteristic of the color filter 14R and the spectral characteristic of the color filter 14G. A spectral characteristic curve of a conventional green color filter is indicated by a thin dotted line as “Conventional Green”, and has a mountain shape with gentle inclinations. When the thin yellow (Y1) color filter is stacked on a conventional green color filter G′ as shown in FIG. 2(c), transmittance decreases for the amount of increase in the filter layer thickness, and the spectral characteristic becomes that of a color filter consisting of the conventional green color filter G′+yellow (Y1) with thin film thickness (Conventional Green+Yellow). Further, if the layer thickness of the conventional green color filter G′ is made thinner and the thin yellow (Y1) color filter is stacked thereon to create a new green color filter G (New Green; new green having a steep spectral characteristic skewed towards the short wavelength), a spectral characteristic curve of the new green color filter becomes that indicated by a thick solid line with expanded dynamic range shown by the arrows. This is precisely the green (G) color layer (green (G1) color layer+yellow (Y1) color layer) of the green color filter 14G in the two-layer configuration shown in FIG. 2(b). The green (G1) color layer itself has a steep spectral characteristic skewed toward the short wavelength. The spectral characteristic curve of the new green color filter indicated by the solid line is shown to the outside of the solid line indicating the spectral characteristic of the color filter consisting of the conventional green color filter+the thin yellow (Y1) color filter, and has a mountain shape with steeper inclinations compared to the color filter consisting of the conventional green color filter+the thin yellow (Y1) color filter. Thus, in comparison between the new green and the conventional green, the new green is steeper, and the height difference of the steps of its mountain shape is greater, and has a wider dynamic range, thereby improving color separation and light reception sensitivity.

In summary, in FIG. 3, even if the color layer with the spectral characteristic of the yellow (Y1) indicated by the thick dotted line as “Yellow” is simply added to the color layer with the spectral characteristic of the conventional green color filter indicated by the thin dotted line as “Conventional Green”, it merely results in a color filter with a spectral characteristic with a mountain shape indicated by the thin solid line as “Conventional Green+Yellow”. However, it is important that the layer thickness of the conventional green color filter “Conventional Green” be set thin to form the green (G1) color layer in the present invention. Thereby, the spectral characteristic of the two-layer configuration (green (G1) color layer+yellow (Y1) color layer) in FIG. 2(b) indicated by the thick solid line as “New Green” obtains the spectral characteristic of a steeply inclined mountain shape with a high range of transmissivity of the green (G) color layer of the color filter 14G. Thus, a spectral characteristic with improved sensitivity and color separation is realized as indicated by the arrows, enabling production of a clearer image. It can be seen that, in comparison to the spectral characteristic of the mountain shape indicated by the thin dotted line as “Conventional Green”, by merely stacking the color layer with the spectral characteristic indicated by the thick dotted line as “Yellow” onto the conventional green color layer, the transmittance of the color filter with the spectral characteristic of a simple mountain shape indicated by the thin solid line as “Conventional Green+Yellow” becomes greater than zero percent and less than or equal to 10 percent (greater than or equal to 0.5 percent and less than or equal to 10 percent) at an optical wavelength of 450 nm. In this case, the transmittance to an optical wavelength at the spectral characteristic of green (G) of the green (G) color layer of the color filter 14G in the two-layer configuration shown in FIG. 2(b), at an optical wavelength of 450 nm, is greater than zero percent and less than or equal to 10 percent (greater than or equal to 0.5 percent and less than or equal to 10 percent), whereas the transmittance of the green (G) color layer of the conventional color filter indicated by the thin dotted line as “Conventional Green” is approximately 25 percent. Also, the transmittance to an optical wavelength at the spectral characteristic of green (G) of the green (G) color layer of the color filter 14G in the two-layer configuration shown in FIG. 2(b), at an optical wavelength of 500 nm, is greater than or equal to 60 percent and less than or equal to 90 percent, whereas the transmittance of the green (G) color layer of the conventional color filter indicated by the thin dotted line as “Conventional Green” is approximately 60 percent. Further, the transmittance to an optical wavelength at the spectral characteristic of green (G) of the green (G) color layer of the color filter 14G in the two-layer configuration shown in FIG. 2(b), at an optical wavelength of 650 nm, is greater than zero percent and less than or equal to 20 percent (greater than or equal to 0.5 percent and less than or equal to 20 percent), whereas the transmittance of the green (G) of the conventional color filter is approximately 24 percent. From the above description, it can be seen how steeply inclined the mountain shape of the spectral characteristic of the green (G) color layer of the color filter 14G is, and how the transmittance range is increased. The spectral characteristic can be controlled to be in this spectral characteristic range by using the New Green filter, in which a thin filter with a Yellow component is added to a filter made by thinning the Conventional Green filter.

Thus, by using the New Green filter in which the thin filter with the Yellow component is added to the filter made by thinning the Conventional Green filter, color noise of the Green filter towards the short wavelength can be suppressed, color reproduction is improved, and sensitivity to Green can be improved. Improvement in sensitivity to Green is about 10 percent.

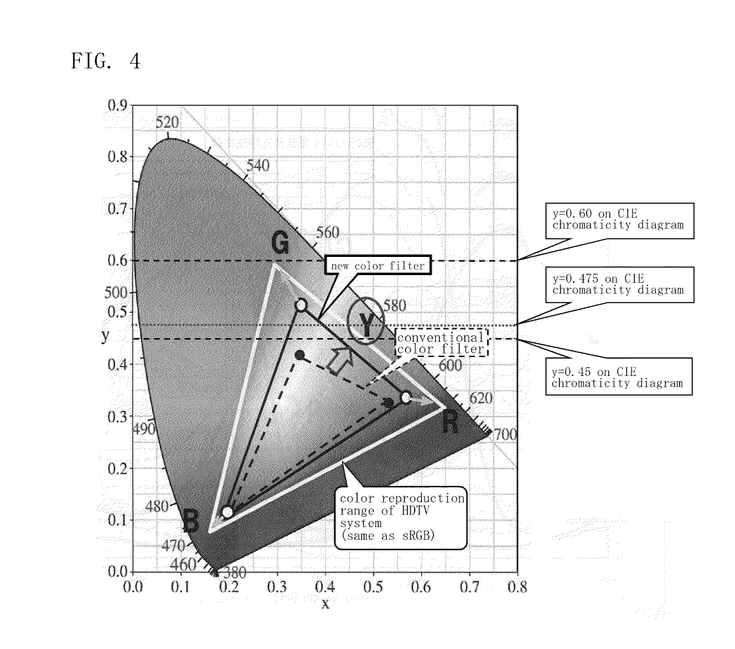

FIG. 4 is a diagram showing the relationship between three primary colors RGB of the conventional color filter and three primary colors RGB of the color filter 14 of Embodiment 1 shown on a CIE chromaticity diagram.

As shown in the CIE chromaticity diagram in FIG. 4, a triangle formed by connecting three points of the primary colors RGB of the conventional color filter is shown by the dotted line, and a triangle formed by connecting three points of the primary colors RGB of the color filter 14 of Embodiment 1 is shown by a solid line. It can be seen that the CIE chromaticity range of the color filter 14 of Embodiment 1 extends further towards the yellow (Y) than the CIE chromaticity range of the conventional color filter. A triangle shown by an outermost white solid line is the location of three points of the primary colors RGB of high-definition TV. In the case with conventional color filters, drastic corrections of extending the three points of the primary colors RGB of the conventional filter to the location of the three points of the three primary colors RGB of high-definition TV are made by internal signal processing, resulting in increasing noise. However, since the correction to the color filter 14 of Embodiment 1 to the location of the three points of the three primary colors RGB of high-definition TV is less drastic in comparison to the conventional correction, color corrections can be made easily and accurately, leading to reduction in color noise and production of a clear image.

In summary, since a chromaticity range can be extended on the CIE chromaticity diagram from the three points of the three primary colors RGB of the conventional filter to the three points of the three primary colors of the color filter 14 of Embodiment 1 by the color filters themselves, load on color corrections by internal signal processing is mitigated and a clearer image can be produced. Specifically, by making the spectral characteristic of the green (G) color filter to be the steeply inclined spectral characteristic with a high transmissivity range of the new green (G) color layer, and adding the yellow (Y1) color layer thereto, the chromaticity range can be extended towards the yellow (Y) including the red (R) on the CIE chromaticity diagram, thereby facilitating the production of yellow (Y) and obtaining a clearer image. In this case the y-axis value of the green (G) color filter of the color filter 14G is greater than or equal to 0.45 on the CIE chromaticity diagram. In such a manner, when the position on the y-axis of the CIE chromaticity diagram of the green (G) of the color filter 14G is greater than or equal to 0.45, the green (G) of the color filter 14G can be closer to the green (G) of high-definition TV by 0.03 compared to the position on the y-axis of the CIE chromaticity diagram of the green (G) of the conventional filter (0.42). In other words, the green (G) of the color filter 14G moves closer to the position on the y-axis of the CIE chromaticity diagram of the ideal green (G) of high-definition TV (0.60), thereby producing less noise and improving color reproduction markedly.

RGB chromaticity coordinates of the color filter 14 of Embodiment 1 using the New Green are extended especially in the yellow region compared to the case in which the conventional color filter is used, and the color filter 14 of Embodiment 1 using the New Green excels in the color reproduction of yellow (Y).

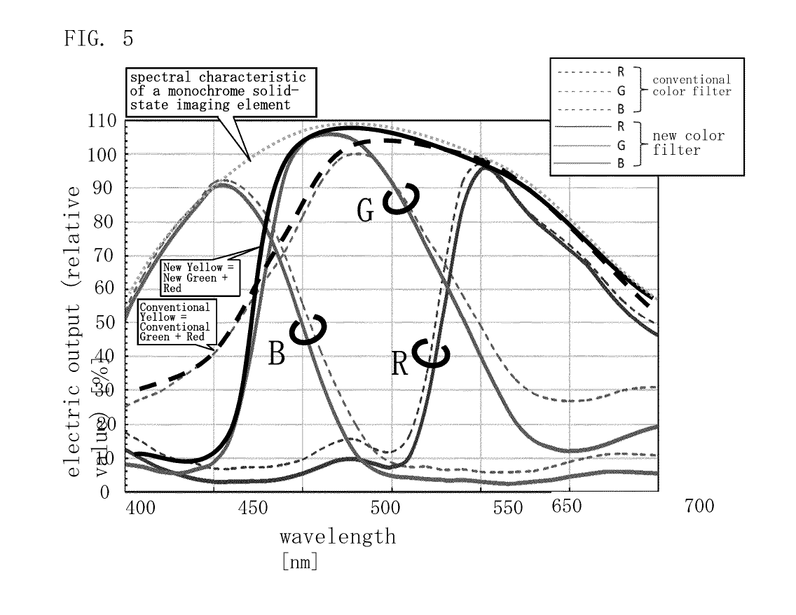

FIG. 5 is an electric spectral characteristic diagram of three primary colors RGB of the color filter in Embodiment 1 of a device and three primary colors RGB of the conventional color filter of a device when the peak value of the spectral characteristic of the green (G) of the conventional color filter indicated by a dotted line is set to be 100 percent. The electric spectral characteristic has a characteristic obtained by multiplication of the color filter spectral characteristic and a device (monochrome) spectral characteristic.

As show in FIG. 5, three primary colors RGB of the conventional color filter are indicated by dotted lines, and three primary colors RGB of the color filter 14 of Embodiment 1 are indicated by solid lines. The green (G) of the color filter 14 of Embodiment 1 indicated by the solid line has a more steeply inclined rise, and larger range of transmissivity compared to the green (G) of the conventional color filter indicated by the dotted line at wavelength 450 nm to 500 nm. The relative electric output value is approximately 10 percent for the green (G) of the color filter 14 of Embodiment 1 indicated by the solid line, whereas the relative electric output value is approximately 40 percent for the green (G) of the conventional color filter at, for example, wavelength 450 nm. Also, the relative electric output value is approximately 100 percent for the green (G) of the color filter 14 of Embodiment 1 indicated by the solid line, whereas the relative electric output value is approximately 80 percent for the green (G) of the conventional color filter at, for example, wavelength 500 nm. Further, the relative electric output value is approximately 10 percent for the green (G) of the color filter 14 of Embodiment 1 indicated by the solid line, whereas the relative electric output value is approximately 30 percent for the green (G) of the conventional color filter at, for example, wavelength 650 nm.

When sections of three primary colors RGB in FIG. 5 overlapping one another are compared, for an area of an overlapping section of the green (G) and the blue (B) of the conventional color filters indicated by dotted lines and an area of an overlapping section of the green (G) and the blue (B) of the color filters 14 of Embodiment 1 indicated by solid lines, the area of the overlapping section of the green (G) and the blue (B) of the color filters 14 of Embodiment 1 indicated by solid lines is overwhelmingly smaller corresponding to the amount of change in steepness and transmissivity range. As the overlapping area of the green (G) and the blue (B) of the color filter 14 becomes larger, the color noise increases, resulting in dull colors. Similarly, for an area of an overlapping section of the green (G) and the red (R) of the conventional color filters indicated by dotted lines and an area of an overlapping section of the green (G) and the red (R) of the color filters 14 of Embodiment 1 indicated by solid lines, the area of the overlapping section of the green (G) and the red (R) of the color filters 14 of Embodiment 1 indicated by the solid lines is smaller corresponding to the amount of change in steepness and transmissivity range. As the overlapping area of the green (G) and the blue (R) of the color filter 14 becomes larger, the color noise increases, resulting in dull colors.

In the case with the green (G) of the conventional color filter, the ratio of the area of the overlapping section of the spectral characteristics of the green (G) and the blue (B) to the spectral characteristic of the green (G) is approximately 36 percent, and the ratio of the area of the overlapping section of the spectral characteristics of the green (G) and the red (R) to the spectral characteristic of the green (G) is approximately 24 percent. In contrast, the ratio of the area of the overlapping section of the spectral characteristics of the green (G) and the blue (B) to the spectral characteristic of the green (G) of the color filter 14 of Embodiment 1 is approximately 23 percent, and the ratio of the area of the overlapping section of the spectral characteristics of the green (G) and the red (R) to the spectral characteristic of the green (G) of the color filter 140f Embodiment 1 is approximately 18 percent. In the case with the color filter 14 of Embodiment 1, when shown in ranges to reduce the overlapping area compared to the conventional filter, the ratio of the area in which the spectral characteristic of the green (G) overlaps the spectral characteristic of the blue (B) is 23 percent±10 percent, and the ratio of the area in which the spectral characteristic of the green (G) overlaps the spectral characteristic of the red (R) is 18 percent±5 percent.

Thus, “Yellow” is reproduced by “Green”+“Red”. On the other hand, a new “Yellow” reproduced by the new “Green”+“Red” has a larger dynamic range of colors and has a smaller area where colors overlap with one another compared to the conventional “Yellow” reproduced by the conventional “Green”+“Red”. Thereby, a clear image is reproduced with little color noise and “Yellow” is especially reproduced clearly without changing color signal processing of a device to match the new color filter arrangement.

The manufacturing method of the CCD solid-state imaging element 1 of Embodiment 1 in the configuration described above comprises: a light reception sections formation step of forming a plurality of light reception section 3 for photo-electrically converting and capturing an image of incident light, on a semiconductor substrate 2 (or a semiconductor layer) in a two-dimensional pattern; a charge transfer means formation step of forming a charge transfer section 4 and a gate electrode 6 thereon adjacent each light reception section 3 as the means for transferring charges; a light shield film formation step of forming a light shield film 9 which covers the gate electrode 6 and is opened above the light reception section 3; a first interlayer insulation film formation step of forming an interlayer insulation film 11 on the step section between the light reception section 3 and the light shield film 9; an inner-layer lens formation step of forming a concave inner-layer lens 12 on the interlayer insulation film 11 in such a manner to match the position of each light reception section 3; a second interlayer insulation film formation step of forming an interlayer insulation film 13 to fill uneven spaces between the inner-layer lenses 12; a color filters formation step of forming color filters 14 in a predetermined color arrangement (for example, a Bayer color arrangement) on the interlayer insulation film 13 in such a manner to match the position of each light reception section 3; and a microlens formation step of forming a microlens 16 on the color filters 14 with a planarizing film 15 interposed therebetween in such a manner to match the position of each light reception section 3.

In the color filter formation step, processing proceeds as follows. A photolithography step is repeated on each photosensitive color filter material, and a color filter 14G1, a color filter 14R and a color filter 14B are formed sequentially in the Bayer arrangement. Then, by forming a color filter 14Y1 on the color filter 14G1, a two-layer configuration can be made with the color filter 14Y1 formed on the color filter 14G1 as a color filter 14G. Colors forming the color filters can be in any order.

From the above, according to Embodiment 1, the film thickness of a green (G) color layer in the Bayer color arrangement is made thin to be the green (G) color layer having a steeply inclined spectral characteristic, with a high range of transmissivity, extended towards the short wavelength, and a yellow (Y1) color layer with a thin film thickness is newly stacked on the thinned green (G1) color layer. Thereby the y-axis value of the spectral characteristic of the green (G) of the green (G) color layer becomes greater than or equal to 0.45 and less than or equal to 0.60 (preferably, greater than or equal to 0.475 and less than or equal to 0.60) on a CIE chromaticity diagram. Thus, color noise is markedly reduced, color reproduction is improved, and a clear image can be obtained without needing to change color signal processing of a device in such a manner to match a new color filter color arrangement.

In Embodiment 1, in the CCD solid-state imaging element 1, the green (G) color layer of the color filter 14G in the Bayer color arrangement has a two-layer configuration consisting of: the green (G1) color layer with the layer thickness made thinner compared to the layer thickness of the layer region other than the green (G) color layer, namely the color filter 14R or 14B (color filter 14G1); and the yellow (Y1) color layer with a thin layer thickness compared to the layer thickness of the layer region other than the green (G) color layer, namely the color filter 14R or 14B (color filter 14Y1), but the green color layer is not limited to this configuration. As shown in FIG. 2(d), the green (G) color layer of the color filter 14G in the Bayer color arrangement may be configured such that: the green (G) color layer is divided in a longitudinal direction or a transverse direction in a plane view; one of the divided regions is configured with a green (G2) color layer; and the other divided region is configured with a yellow (Y2) color layer. In this case, respective area regions of the green (G2) color layer on the left and the yellow (Y2) color layer on the right are equal to each other in a plane view. The CCD solid-state imaging element 1 can also be configured in this manner.

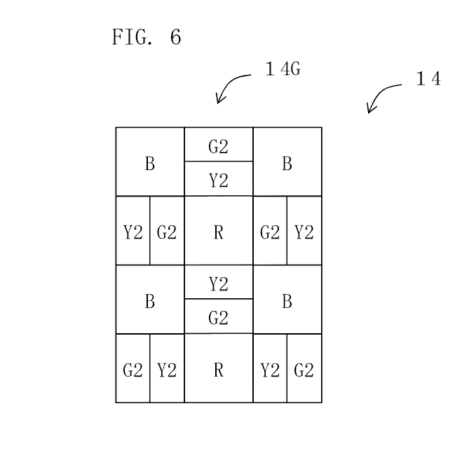

In this case, as shown in FIG. 6, the Bayer color arrangement of the color filter 14 can be shown in a minimum repeating adjacent four-pixel unit. However, when the color filter 14R is centered, color filters 14G surround the top, bottom, left, and right side of the color filter 14R. In the color filter 14G on the top side of the color filter 14R, the color filter 14G2 and the color filter 14Y2 are arranged in that order from the top in a longitudinal direction. In the color filter 14G on the bottom side of the color filter 14R, the color filter 14Y2 and the color filter 14G2 are arranged in that order from the top in the longitudinal direction. In this fashion, the arrangement of the color filter 14G2 and the color filter 14Y2 in the color filter 14G is such that the color filter 14Y2 and the color filter 14G2 are arranged in an alternating order for each minimum repeating adjacent four-pixel unit in the Bayer color arrangement.

Also, when the color filter 14R is centered, color filters 14G surround the top, bottom, left, and right side of the color filter 14R. In the color filter 14G on the left side of the color filter 14R, the color filter 14Y2 and the color filter 14G2 are arranged in that order from left to right in the transverse direction. In the color filter 14G on the right side of the color filter 14R, the color filter 14G2 and the color filter 14Y2 are arranged in that order from left to right in the transverse direction. In this fashion, the arrangement of the color filter 14Y2 and the color filter 14G2 in the color filter 14G is also such that the color filter 14Y2 and the color filter 14G2 are arranged in an alternating order for each minimum repeating adjacent four-pixel unit in the Bayer color arrangement.

For this reason, even if a border line of the green (G) color layer divided in the longitudinal direction or the transverse direction in the plane view is offset in the longitudinal direction and the transverse direction in the plane view, colors are not biased to the green (G2) or the yellow (Y2).

To explain further, in Embodiment 1, each of the green (G) color layer (G1+Y1) and the green (G1) color layer has the steeply inclined spectral characteristic with a high range of transmissivity extended towards the short wavelength compared to the conventional green (G). Further, each of the green (G) color layer (G2+Y2) and the green (G2) color layer also has the steeply inclined spectral characteristic with a high range of transmissivity extended towards the short wavelength compared to the conventional green (G).

In Embodiment 1, in the CCD solid-state imaging element 1, the green (G) color layer of the color filter 14G in the Bayer color arrangement has the two-layer configuration consisting of: the green (G1) color layer (color filter 14G1) with the layer thickness made thinner compared to the layer thickness of the layer region other than the green (G) color layer, namely the color filter 14R or 14B; and the yellow (Y1) color layer (color filter 14Y1) with the thinner layer thickness compared to the layer thickness of the layer region other than the green (G) color layer, namely the color filter 14R or 14B. Alternatively, as a example of a variation thereof, the green (G) color layer of the color filter 14G in the Bayer color arrangement is configured such that the green (G) color layer is divided in the longitudinal or the traverse direction in the plane view, one of the divided regions consisting of the green (G2) color layer, and the other divided region consisting of the yellow (Y2) color layer. However, these configurations of the present invention are not limited to the CCD solid-state imaging element 1, but can also be applied to a CMOS solid-state imaging element.

### Embodiment 2

In Embodiment 1, in the CCD solid-state imaging element 1, the green (G) color layer of the color filter 14G in the Bayer color arrangement is divided in the direction of the layer thickness to form the two-layer configuration consisting of the green (G1) color layer (color filter 14G1) and the yellow (Y1) color layer (color filter 14Y1), or divided at the region in plane view to form the adjacent configuration in plane view consisting of the green (G2) color layer and the yellow (Y2) color layer. However, in Embodiment 2, in a CMOS solid-state imaging element, instead of the two-layer configuration consisting of the green (G1) color layer (color filter 14G1) and the yellow (Y1) color layer (color filter 14Y1) or the adjacent configuration in plane view consisting of the green (G2) color layer and the yellow (Y2) color layer, a case where pigments are mixed and combined as a single green (G) color layer will be described in detail. Thus, since spectral characteristics of the green (G) color layers in FIGS. 3 to 5 are exactly the same, detailed description thereof are omitted herein.

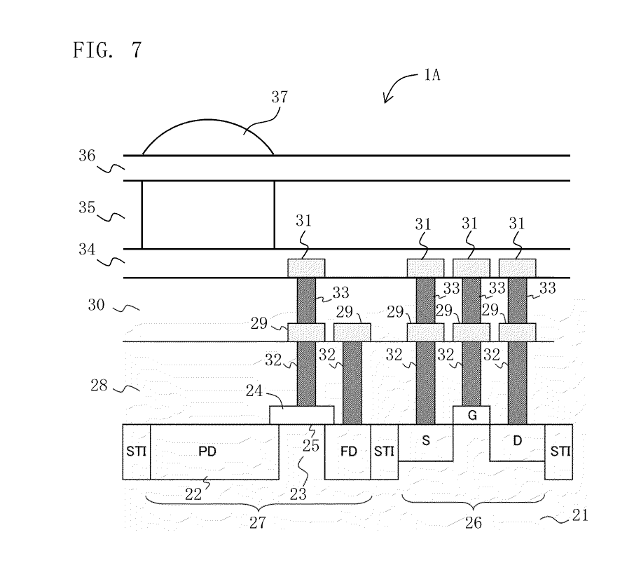

FIG. 7 is a longitudinal cross-sectional view schematically showing an example of a configuration of an essential part of the CMOS solid-state imaging element according to Embodiment 2 of the present invention.

In FIG. 7, a plurality of pixel sections are arranged in a matrix pattern in rows and columns in a CCD solid-state imaging element 1A according to Embodiment 2. In each pixel section thereof, a light reception section 22 is provided as a light reception element which is configured with a photodiode that photo-electrically converts incident light to produce signal charges, on a surface section of a semiconductor substrate 21. A transfer gate 24 is provided, adjacent the light reception section 22, with a gate insulation film 25 interposed therebetween, for transferring charges to a floating diffusion FD functioning as a charge voltage conversion section via a charge transfer section 23 of a charge transfer transistor from the light reception section 22. A charge transfer transistor is configured as a charge transfer means for transferring imaging signals from the light reception section 22 to the floating diffusion FD via the charge transfer section 23, the gate insulation film 25 and the transfer gate 24. Further, each light reception section 22 comprises a readout circuit, in which signal charges transferred to the floating diffusion FD are: converted to voltage; amplified by an amplifier transistor (not shown) in accordance with the converted voltage; and read out as imaging signals for each pixel section.

A circuit wiring section of the readout circuit, and circuit wiring sections connected to the transfer gate 24 and the floating diffusion section FD are provided above the transfer gate 24, the floating diffusion section FD, and a logic transistor region 26. An interlayer insulation film 28 well-suited for embedding between wirings made thin is formed on the gate insulation film 25 and the transfer gate 24. An interlayer insulation film 30 well-suited for embedding between wirings made thin is formed thereon, and a second wiring layer 31 is formed thereon. Thereby the circuit wiring section is configured. Respective contact plugs 32 made of conductive material (for example, tungsten) are also formed: between the wiring layer 29 and the transfer gate 24; between the wiring layer 29 and the floating diffusion section FD; and between the wiring layer 29 and each of a source (S), a drain (D), and a gate (G) of the logic transistor region 26. A contact plug 33 is formed between each wiring layer 29 and a wiring layer 31 thereabove. Wiring layers 29 and 31 made of aluminum or copper electrically connects to their respective transfer gate 24, floating diffusion section FD and the source (S), the drain (D), and the gate (G) of the logic transistor region 26.

An interlayer insulation film 34 is formed to fill in the difference in height on the interlayer insulation film 30 and each wiring layer 31. Color filters 35 with a predetermined color arrangement (for example, the Bayer arrangement) of each color R, G, and B placed at each light reception section 22 are formed on the interlayer insulation film 34. Further, a planarizing film 36 is formed on the color filters 35, and a microlens 37 for gathering light to the light reception section 22 is additionally formed on the planarizing film 36.

In this case, similar to the color filters 14 of Embodiment 1, color filters 35 are arranged in plane view in such a manner to match a red (R) color layer, a green (G) color layer, and a blue (B) color layer of the three primary colors in a predetermined color arrangement, for example the Bayer arrangement, to each light reception section 22. In Embodiment 2, in a CMOS solid-state imaging element 1A, the configuration that coloring matters are mixed to be a single green (G) color layer is what is different from Embodiment 1, which has the two-layer configuration consisting of the green (G1) color layer (color filter 14G1) and the yellow (Y1) color layer (color filter 14Y1) or the adjacent configuration in the plane view consisting of the green (G2) color layer and the yellow (Y2) color layer.

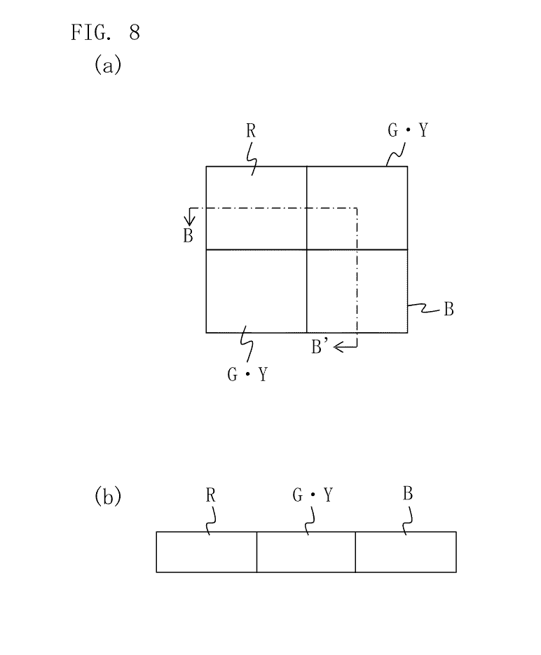

In the color filter 35 in Embodiment 2, similar to the case with color filter 14 in Embodiment 1, as shown in FIG. 4, a spectral characteristic of green (G) of a single-layered green (G) color layer also has the y-axis value greater than or equal to 0.45 and less than or equal to 0.60 on the CIE chromaticity diagram. Also, as shown in FIG. 3, the transmittance to an optical wavelength at the spectral characteristic of green (G) of the single-layered green (G) color layer of the color filter 35 is greater than zero percent and less than or equal to 10 percent (greater than or equal to 0.5 percent and less than or equal to 10 percent) at an optical wavelength of 450 nm. Also, the transmittance to an optical wavelength at the spectral characteristic of green (G) of the single-layered green (G) color layer is greater than or equal to 60 percent and less than or equal to 90 percent at an optical wavelength of 500 nm. Further, the transmittance to an optical wavelength at the spectral characteristic of green (G) of the single-layered green (G) color layer is greater than zero percent and less than or equal to 20 percent (greater than or equal to 0.5 percent and less than or equal to 20 percent) at an optical wavelength of 650 nm. FIG. 8(a) is a plane view schematically showing a minimum repeating unit of the color arrangement of the color filters in FIG. 7, and FIG. 8(b) is a longitudinal cross-sectional view of the color filters in a direction of a line B-B′ of FIG. 8(a).

In FIG. 8(a), the Bayer color arrangement of three primary colors RGB of the color filters 35 is shown in the minimum repeating adjacent four-pixel unit. A red (R) color layer and a blue (B) color layer of the Bayer color arrangement of the color filters 35 are arranged in a diagonal direction in the plane view, and a green (G•Y) color layer of the Bayer arrangement of the color filters 35 is each arranged in the opposite diagonal direction. In FIG. 8(b), the green (G•Y) color layer of the color filters 35 is placed between the red (R) color layer and the blue (B) color layer of the color filters 35 in a longitudinal cross-sectional configuration.

In summary, the green (G) color layer of the color filter 35 is a single-layered green (G•Y) color layer so configured to obtain the spectral characteristics shown in FIGS. 3 and 4, and coloring matters such as various types of pigments are mixed into base material such as clear acrylic. Thus, the spectral characteristic of single-layered green (G•Y) color layer of the color filter 35 is similar to the spectral characteristic of the two-layer configuration in Embodiment 1 consisting of the green (G1) color layer (color filter 14G1) and the yellow (Y1) color layer (color filter 14Y1) with the green (G) color layer of the color filter 14G in the Bayer color arrangement divided in the direction of the film thickness, and the spectral characteristic of the adjacent configuration in the plane view in Embodiment 1 consisting of the green (G2) color layer and yellow (Y2) color layer with divided green (G) color layer of the color filter 14G in the Bayer color arrangement divided at the region in plane view.

A manufacturing method of a CMOS solid-state imaging element 1A according to Embodiment 2 in the configuration described above comprises: alight reception section formation step of forming a plurality of light reception sections 22 for photo-electrically converting and capturing an image of incident light, in a semiconductor substrate 21 (or a semiconductor layer); a charge transfer means formation step of forming a charge transfer section 23 and a transfer gate 24 adjacent each light reception section 22 as a means for transferring charges; a first interlayer insulation film formation step of forming an interlayer insulation film 28 above the light reception section 22 and the transfer gate 24; a first contact plug formation step of forming within the interlayer insulation film 28 each contact plug 32 connected to the respective transfer gate 24 or the charge voltage conversion region (floating diffusion section FD) which is the destination of a charge transfer; a first wiring section formation step of forming each first wiring layer 29 on the interlayer insulation film 28 so as to connect to the respective contact plug 32; a second interlayer insulation film formation step of forming an interlayer insulation film 30 on the interlayer insulation film 28 and each first wiring layer 29; a second contact plug formation step of forming within the interlayer insulation film 30 each second contact plug 33 connecting to the respective first wiring section 29; a second wiring section formation step of forming each second wiring layer 31 so as to connect to the respective second contact plug 33; a third interlayer insulation film formation step of forming an interlayer insulation film 34 on the interlayer insulation film 30 and each second wiring layer 31; a color filter formation step of forming color filters 35 (R, G, Y, and B) in a predetermined color arrangement, for example a Bayer color arrangement, in such a manner to match the location of each light reception section 22 on the interlayer insulation film 34; and a microlens formation step of forming a microlens 37 above the color filters 35 with a planarizing film 36 interposed therebetween in such a manner to match the location of each light reception section 22.

In the color filter formation step, in such a manner to match the location of each light reception section 22, a photolithography step is repeated on each photosensitive color filter material to form a color filter 35 (G•Y) in the Bayer color arrangement; and further a color filter 35R in the Bayer color arrangement is formed, and a color filter 35B in the Bayer color arrangement is successively formed. Color filters of different colors can be made in any order, and any order can be used for forming the color filters.

As for the material of the color filter 35 (G•Y), as mentioned previously in regards to Embodiment 1, the two-layer configuration consisting of the green (G1) color layer (color filter 14G1) and the yellow (Y1) color layer (color filter 14Y1), or the adjacent configuration in the plane view consisting of the green (G2) color layer and the yellow (Y2) color layer, is used as a single green (G) layer, and color pigments dispersed in base resin material containing acrylic material are used. The color filter 35 (G•Y) is made by adjusting the pigment quantitatively. As a result, the spectral characteristic of the green (G) color layer of the color filter 14G of FIG. 1 is steep and skewed towards the short wavelength compared to the conventional green (G) color layer, as shown in FIGS. 3 and 5. The green (G) color layer having such a spectral characteristic can be adjusted easily according to the specification thereof.

Specifically, photo-sensitive color filter formation material (color resist) with a desirable spectral characteristic can be obtained by choosing, mixing, and dispersing two or more types of pigments, namely compounds labeled with a Colour Index (C.I.) number listed below, categorized as a pigment by the Colour Index (C.I.: published by The Society of Dyers and Colourists), and adding necessary amount of photopolymerization initiator and surfactant. For example, green pigments include C.I. pigment green 7 and 36, and yellow pigments include C.I. pigment yellow 12, 83, and 150. A blue or red pigment may also be added as needed.

In Embodiment 1, the manufacturing step of the color filter 14 has become complicated and the manufacturing time is increased due to making the film thickness of the green in the Bayer color arrangement thinner and newly adding the yellow. However, according to Embodiment 2 as described above, since the yellow is added to the green in the Bayer color arrangement having the spectral characteristic extended towards the short wavelength, steeply inclined and with a high transmissivity range, to be the new green to form the color filter with the single layer configuration, improvement in color reproduction can be realized, without complicating the manufacturing step of the color filter 35, at low cost. Additionally, since the spectral characteristic of the green (G) of the green (G) color layer has a y-axis value greater than or equal to 0.45 and less than or equal to 0.60 on the CIE chromaticity diagram, color noise is markedly reduced and color reproduction is improved, thus producing a clear image without changing the color signal processing of a device in such a manner to match the new color filter color arrangement.

### Embodiment 3

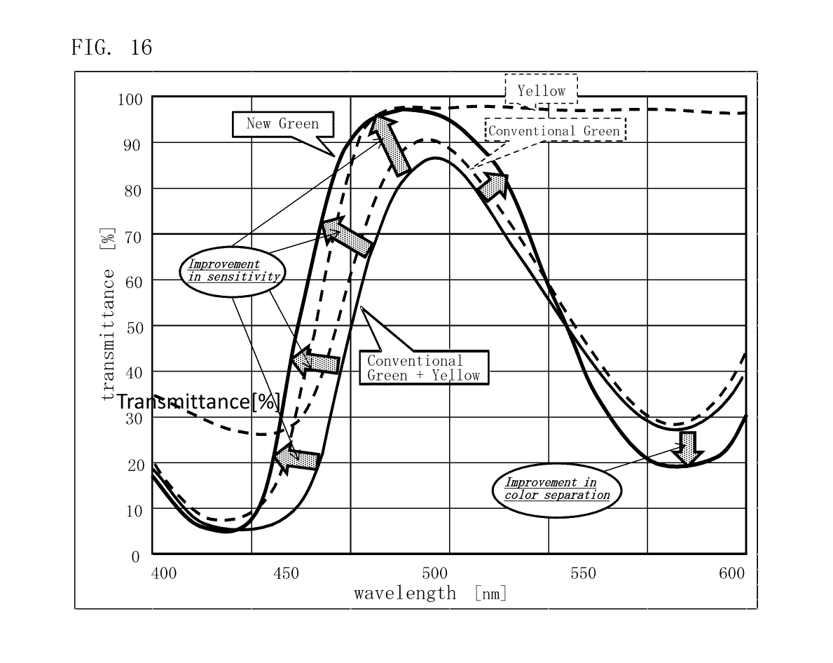

In Embodiment 1, in the CCD solid-state imaging element 1, the green (G) color layer of the color filter 14G in the Bayer color arrangement is divided in the direction of the layer thickness, or divided at the region in the plane view, and then made into the two-layer configuration consisting of the green (G1) color layer (color filter 14G1) and the yellow (Y1) color layer (color filter 14Y1) (color arrangement order may be reversed in the direction of the layer thickness), or made into the adjacent configuration in the plane view consisting of the green (G2) color layer and the yellow (Y2) color layer (left-right or top-bottom order may be reversed). However, in Embodiment 3, with regard to a CCD solid-state imaging element, a case in which the two layer configuration consisting of the green (G1) color layer (color filter 14G1) and the yellow (Y1) color layer (color filter 14Y1), or the adjacent configuration in the plane view consisting of the green (G2) color layer and the yellow (Y2) color layer, as shown in FIG. 1, is integrated as a single layer by mixing color matters will be described in detail. In this case, the description will use spectral characteristics in FIG. 16 in which the relationship between transmittance and optical wavelength of the green color layer (color filter) with mixed color matters actually measured separately is shown.

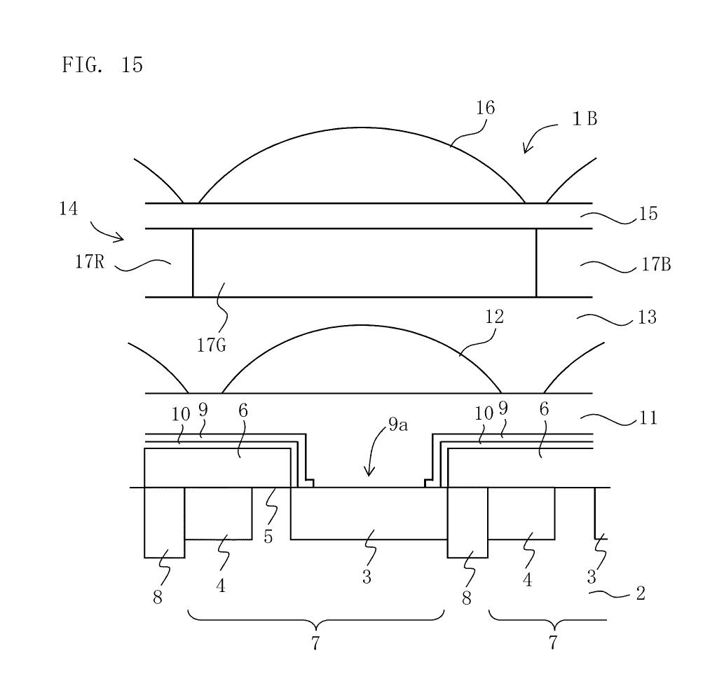

FIG. 15 is a longitudinal cross-sectional diagram schematically showing an example of a configuration of an essential part of a CCD solid-state imaging element in Embodiment 3 of the present invention. Members having similar functional effect to the configuration member of the CCD solid-state imaging element in FIG. 1 are added with the same reference numerals, but their explanations will be omitted.

In FIG. 15, differences between a CCD solid-state imaging element 1B in Embodiment 3 and the solid-state imaging element 1 in Embodiment 1 are color filters 17R, 17G, and 17B formed on an interlayer insulation film 13. Color filters 17R, 17G, and 17B form a predetermined color arrangement (for example a Bayer color arrangement) of R, G, and B placed at each light reception section 3. In this case, the color filter 17G integrates the two layer configuration consisting of the green (G1) color layer (color filter 14G1) and the yellow (Y1) color layer (color filter 14Y1) in FIG. 1, or the adjacent configuration in the plane view consisting of the green (G2) color layer and the yellow (Y2) color layer in FIG. 1 into a single green color layer by mixing color matters.

FIG. 16 is a spectral characteristic diagram showing the relationship between transmittance and optical wavelength of the green (G) color layer of the color filter 17G in FIG. 15.

As shown in FIG. 16, the spectral characteristic of the yellow (Y1) indicated by a dotted line as “Yellow” is obtained by processing signals using the spectral characteristic of the color filter 17R and the spectral characteristic of the color filter 17G. A spectral characteristic curve of a conventional green color filter is indicated by a thin dotted line as “Conventional Green”, and has a mountain shape with gentle inclinations. When the thin yellow (Y1) color filter is stacked on the conventional green color filter G′ as shown in FIG. 2(c), transmittance decreases for the amount of increase in the filter layer thickness, and the spectral characteristic becomes that of a color filter consisting of the conventional green color filter G′+yellow (Y1) with thin film thickness (Conventional Green+Yellow). Further, if the layer thickness of the conventional green color filter G′ is made thinner and the thin yellow (Y1) color filter is stacked thereon to create a new green color filter G (New Green; new green having a steep spectral characteristic skewed towards the short wavelength), a spectral characteristic curve of the new green color filter becomes that indicated by a solid line with expanded dynamic range shown by the arrows. This is precisely the green (G) color layer (green (G1) color layer+yellow (Y1) color layer) of the green color filter 14G in the two-layer configuration shown in FIG. 2(b) integrated into a single green (G•Y) color layer of the color filter 17G by mixing color matters as shown in FIG. 8(b). The green (G1) color layer itself has a steep spectral characteristic skewed toward the short wavelength. The spectral characteristic curve of the new green color filter indicated by the solid line is shown to the outside of the solid line indicating the spectral characteristic of the color filter consisting of the conventional green color filter+the thin yellow (Y1) color filter, and has a mountain shape with steeper inclinations compared to the color filter consisting of the conventional green color filter+the thin yellow (Y1) color filter. Thus, in comparison between the new green and the conventional green, the new green is steeper, and the height difference of the steps of its mountain shape is greater, and has a wider dynamic range, thereby improving color separation and light reception sensitivity.

In summary, in FIG. 16, even if the color layer with the spectral characteristic of the yellow (Y1) indicated by the thick dotted line as “Yellow” is simply added to the color layer with the spectral characteristic of the conventional green color filter indicated by the thin dotted line as “Conventional Green”, it merely results in a color filter with a spectral characteristic with a mountain shape indicated by the thin solid line as “Conventional Green+Yellow”. However, it is important that the layer thickness of the conventional green color filter “Conventional Green” be set thin to form the green (G1) color layer in the present invention. Thereby, the spectral characteristic of the two-layer configuration (green (G1) color layer+yellow (Y1) color layer) in FIG. 2(b) indicated by the thick solid line as “New Green” obtains the spectral characteristic of a steeply inclined mountain shape with a high range of transmissivity of the green (G) color layer of the color filter 14G. Thus, a spectral characteristic with improved sensitivity and color separation is realized as indicated by the arrows, enabling production of a clearer image. It can be seen that, in comparison to the spectral characteristic of the mountain shape indicated by the thin dotted line as “Conventional Green”, by merely stacking the color layer with the spectral characteristic indicated by the thick dotted line as “Yellow” onto the conventional green color layer, the transmittance of the color filter with the spectral characteristic of a simple mountain shape indicated by the thin solid line as “Conventional Green+Yellow” becomes greater than or equal to zero percent and less than or equal to 20 percent at an optical wavelength of 450 nm. In this case, the transmittance to an optical wavelength at the spectral characteristic of green (G•Y) of the green (G•Y) color layer of the color filter 17G in the single layer configuration shown in FIG. 15, at an optical wavelength of 450 nm, is greater than zero percent (greater than or equal to 0.5 percent) and less than or equal to 20 percent, whereas the transmittance of the green (G) color layer of the conventional color filter indicated by the thin dotted line as “Conventional Green” is approximately 26 percent. Also, the transmittance to an optical wavelength at the spectral characteristic of green (G•Y) of the green (G•Y) color layer of the color filter 17G in the single layer configuration shown in FIG. 15, at an optical wavelength of 500 nm, is greater than or equal to 60 percent and less than or equal to 98 percent, whereas the transmittance of the green (G) color layer of the conventional color filter indicated by the thin dotted line as “Conventional Green” is approximately 60 percent. Further, the transmittance to an optical wavelength at the spectral characteristic of green (G•Y) of the green (G•Y) color layer of the color filter 17G in the single layer configuration shown in FIG. 15, at an optical wavelength of 650 nm, is greater than zero percent (greater than or equal to 0.5 percent) and less than or equal to 30 percent, whereas the transmittance of the green (G) of the conventional color filter is approximately 30 percent. It can be seen how steeply inclined the mountain shape of the spectral characteristic of the green (G•Y) color layer of the color filter 17G is, and how the transmittance range is increased. The spectral characteristic can be controlled to be in this range by mixing color matters and forming the single layer configuration as the New Green filter, in which a thin filter with a Yellow component is added to a filter made by thinning the Conventional Green filter.

Thus, by using the New Green filter in which the thin filter with the Yellow component is added to the filter made by thinning the Conventional Green filter, color noise of the Green filter towards the short wavelength can be suppressed, color reproduction is improved, and sensitivity to Green can be improved simultaneously. Sensitivity to Green can be improved about 10 percent by using the New Green filter in such a manner.

Thus, the y-axis value of the green (G) color filter of the color filter 17G is greater than or equal to 0.45 and less than or equal to 0.60 (preferably greater than or equal to 0.475 and less than or equal to 0.60) as shown on the CIE chromaticity diagram in FIG. 4. In such a manner, when the position on the y-axis of the CIE chromaticity diagram of the green (G•Y) of the color filter 17G is greater than or equal to 0.45, the green (G•Y) of the color filter 17G can be closer to the green (G) of high-definition TV by 0.03 compared to the position on the y-axis of the CIE chromaticity diagram of the green (G) of the conventional filter (0.42). In other words, the green (G•Y) of the color filter 17G moves closer to the position on the y-axis of the CIE chromaticity diagram of the ideal green (G) of high-definition TV (0.60), thereby producing less color noise and improving color reproduction markedly.

RGB chromaticity coordinates of the color filter 17 of Embodiment 3 using the New Green are extended especially in the yellow region compared to the case in which the conventional color filter is used, and the color filter 17 of Embodiment 3 using the New Green excels in the color reproduction of yellow (Y).

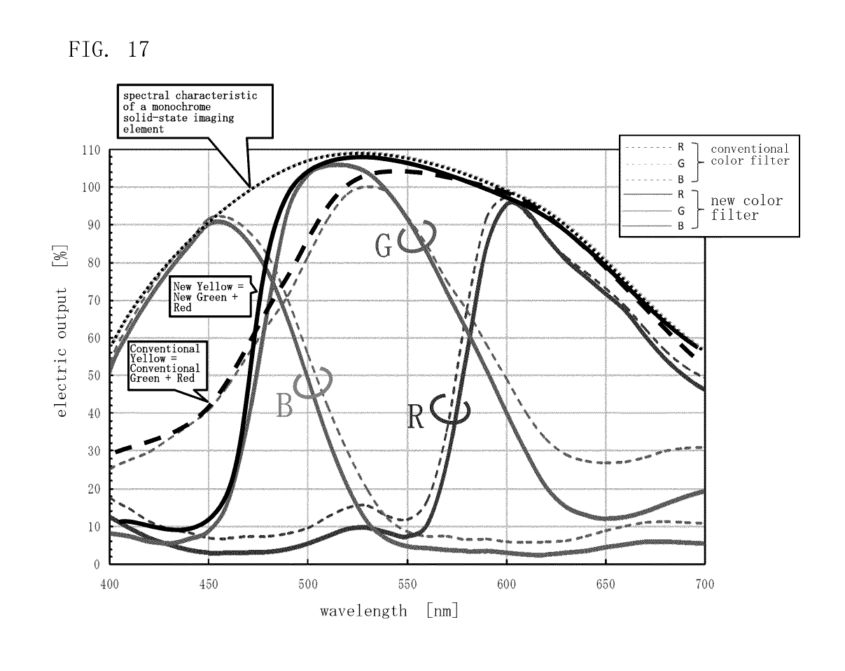

FIG. 17 is an electric spectral characteristic diagram of three primary colors RGB of the color filter in Embodiment 3 of a device and three primary colors RGB of the conventional color filter of a device when the peak value of the spectral characteristic of the green (G) of the conventional color filter indicated by a dotted line is set to be 100 percent. The electric spectral characteristic has a characteristic calculated by the color filter spectral characteristic and a device (monochrome) spectral characteristic multiplied together.

As show in FIG. 17, three primary colors RGB of the conventional color filter are indicated by dotted lines, and three primary colors RGB of the color filter 17R, 17G, and 17B of Embodiment 3 are indicated by solid lines. The green (G•Y) of the color filter 17G amongst color filters 17R, 17G, and 17B of Embodiment 3 indicated by the solid line has a more steeply inclined rise, with a larger range in transmissivity compared to the green (G) of the conventional color filter indicated by the dotted line at wavelength 450 nm to 500 nm. The relative electric output value is approximately 10 percent for the green (G•Y) of the color filter 17G amongst color filters 17R, 17G, and 17B of Embodiment 3 indicated by the solid line, whereas the relative electric output value is approximately 40 percent for the green (G) of the conventional color filter at, for example, wavelength 450 nm. Also, the relative electric output value is approximately 100 percent or greater than or equal to 100 percent for the green (G•Y) of the color filter 17G amongst color filters 17R, 17G, and 17B of Embodiment 3 indicated by the solid line, whereas the relative electric output value is approximately 80 percent for the green (G) of the conventional color filter at, for example, wavelength 500 nm. Further, the relative electric output value is approximately 10 percent for the green (G•Y) of the color filter 17G amongst color filters 17R, 17G, and 17B of Embodiment 3 indicated by the solid line, whereas the relative electric output value is approximately 30 percent for the green (G) of the conventional color filter at, for example, wavelength 650 nm.

When sections of three primary colors RGB in FIG. 17 overlapping one another are compared, for an area of an overlapping section of the green (G) and the blue (B) of the conventional color filters indicated by dotted lines and an area of an overlapping section of the green (G•Y) of the color filter 17G and the blue (B) of the color filter 17B of Embodiment 3 indicated by solid lines, the area of an overlapping section of the green (G•Y) of the color filter 17G and the blue (B) of the color filter 17B of Embodiment 3 indicated by solid lines is overwhelmingly smaller corresponding to the amount of the change in the steepness and the transmissivity range. As the overlapping area of the green (G•Y) of the color filter 17G and the blue (B) of the color filter 17B becomes larger, the color noise increases, resulting in dull colors. Similarly, for an area of an overlapping section of the green (G) and the red (R) of the conventional color filters indicated by dotted lines and an area of an overlapping section of the green (G•Y) of the color filter 17G and the red (R) of the color filter 17R of Embodiment 3 indicated by solid lines, the area of the overlapping section of the green (G•Y) of the color filter 17G and the red (R) of the color filter 17R of Embodiment 3 indicated by the solid lines is smaller corresponding to the amount of the change in the steepness and the transmissivity range. As the overlapping area of the green (G) of the color filter 17G and the red (R) of the color filter 17R becomes larger, the color noise increases, resulting in dull colors.

In the case with the green (G) of the conventional color filter, the ratio of the area of the overlapping section of the spectral characteristics of the green (G) and the blue (B) to the spectral characteristic of the green (G) is approximately 36 percent, and the ratio of the area of the overlapping section of the spectral characteristics of the green (G) and the red (R) to the spectral characteristic of the green (G) is approximately 24 percent. In contrast, the ratio of the area of the overlapping section of the spectral characteristics of the green (G•Y) and the blue (B) to the spectral characteristic of the green (G•Y) of the color filter 17G of Embodiment 3 is approximately 23 percent, and the ratio of the area of the overlapping section of the spectral characteristics of the green (G•Y) and the red (R) to the spectral characteristic of the green (G•Y) of the color filter 17G of Embodiment 3 is approximately 18 percent. In the case with the color filters 17R, 17G, and 17B of Embodiment 3, when shown in ranges, the ratio of the area in which the spectral characteristic of the green (G•Y) overlaps the spectral characteristic of the blue (B) is 23 percent±10 percent, and the ratio of the area in which the spectral characteristic of the green (G•Y) overlaps the spectral characteristic of the red (R) is 18 percent±5 percent.

Thus, “Yellow” is reproduced by “Green”+“Red”. On the other hand, a new “Yellow” reproduced by the new “Green”+“Red” has a larger dynamic range of colors and has a smaller area where colors overlap with one another compared to the conventional “Yellow” reproduced by the conventional “Green”+“Red”. Thereby, a clear image is reproduced with little color noise and “Yellow” is especially reproduced clearly without changing color signal processing of a device to match the new color filter arrangement.

A manufacturing method of the CCD solid-state imaging element 1B of Embodiment 3 in the configuration described above comprises: a light reception sections formation step of forming a plurality of light reception section 3 for photo-electrically converting, and capturing an image of, incident light, in a semiconductor substrate 2 (or a semiconductor layer) in a two-dimensional pattern; a charge transfer means formation step of forming a charge transfer section 4 and a gate electrode 6 thereon adjacent each light reception section 3 as the means for transferring charges; a light shield film formation step of forming a light shield film 9 which covers the gate electrode 6 and is opened above the light reception section 3; a first interlayer insulation film formation step of forming an interlayer insulation film 11 on the step section between the light reception section 3 and the light shield film 9; an inner-layer lens formation step of forming a concave inner-layer lens 12 on the interlayer insulation film 11 in such a manner to match the position of each light reception section 3; a second interlayer insulation film formation step of forming an interlayer insulation film 13 to fill uneven spaces between the inner-layer lenses 12; a color filters formation step of forming color filters 17R, 17G, and 17B in a predetermined color arrangement (for example, a Bayer color arrangement) on the interlayer insulation film 13 in such a manner to match the position of each light reception section 3; and a microlens formation step of forming a microlens 16 on the color filters 17R, 17G, and 17B in this predetermined color arrangement with a planarizing film 15 interposed therebetween in such a manner to match the position of each light reception section 3.

In the color filter formation step, in such a manner to match the location of each light reception section 3, a photolithography step is repeated on each photosensitive color filter material and: a color filter 17G in the Bayer color arrangement is formed; a color filter 17R in the Bayer color arrangement is formed; and further a color filter 17B in the Bayer color arrangement is formed. Any order can be used for forming the color filters.

In Embodiment 1, the manufacturing step of the color filter 14 has become complicated and manufacturing time increased due to making the film thickness of the green in the Bayer color arrangement thinner and newly adding the yellow. However, according to Embodiment 3 as described above, since the yellow is added to the green in the Bayer color arrangement having the steeply inclined spectral characteristic, with a high transmissivity range, extended towards the short wavelength and the color matters are mixed with each other to be the new green (G•Y) to form the color filter with the single layer configuration, improvement in color reproduction can be realized, without complicating the manufacturing step of the color filter 17G, at low cost. Additionally, since the spectral characteristic of the green (G) color layer has a y-axis value greater than or equal to 0.45 and less than or equal to 0.60 (preferably greater than or equal to 0.475 and less than or equal to 0.60) on the CIE chromaticity diagram, color noise is markedly reduced and color reproduction is improved, thus producing a clear image without changing the color signal processing of a device in such a manner to match the new color filter color arrangement.

In Embodiment 3, a case is described where the two layer configuration consisting of the green (G1) color layer (color filter 14G1) and the yellow (Y1) color layer (color filter 14Y1), or the adjacent configuration in the plane view consisting of the green (G2) color layer and the yellow (Y2) color layer in FIG. 1 is integrated into the single layer configuration with a single green color layer by mixing color matters. However, the configuration is not limited to this. The green (G1) color layer and the yellow (Y1) color layer may also be placed separately as the two layer configuration consisting of the green (G1) color layer (color filter 14G1) and the yellow (Y1) color layer (color filter 14Y1) in FIG. 1, or the adjacent configuration in the plane view consisting of the green (G2) color layer and the yellow (Y2) color layer in FIG. 6.

As for the material of the green (G•Y) of the color filter 17G, as mentioned previously in regards to Embodiment 1, the two-layer configuration consisting of the green (G1) color layer (color filter 14G1) and the yellow (Y1) color layer (color filter 14Y1), or the adjacent configuration in the plane view consisting of the green (G2) color layer and the yellow (Y2) color layer, is used as a single green (G) layer, and color pigments dispersed in base resin material containing acrylic material are used. The green (G•Y) of the color filter 17G is made by adjusting the pigment quantitatively. As a result, the spectral characteristic of the green (G•Y) color layer of the color filter 17G of FIG. 15 is steep and skewed towards the short wavelength compared to the conventional green (G) color layer, as shown in FIGS. 16 and 17. The green (G•Y) color layer having such a spectral characteristic can be adjusted easily according to the specification thereof.

Specifically, photo-sensitive color filter formation material (color resist) with a desirable spectral characteristic can be obtained by choosing, mixing, and dispersing two or more types of pigments, namely compounds labeled with a Colour Index (C.I.) number listed below, categorized as a pigment by the Colour Index (C.I.: published by The Society of Dyers and Colourists), and adding the necessary amount of photopolymerization initiator and surfactant. For example, green pigments include C.I. pigment green 7 and 36, and yellow pigments include C.I. pigment yellow 12, 83, and 150. A blue or red pigment may also be added as needed.

### Embodiment 4

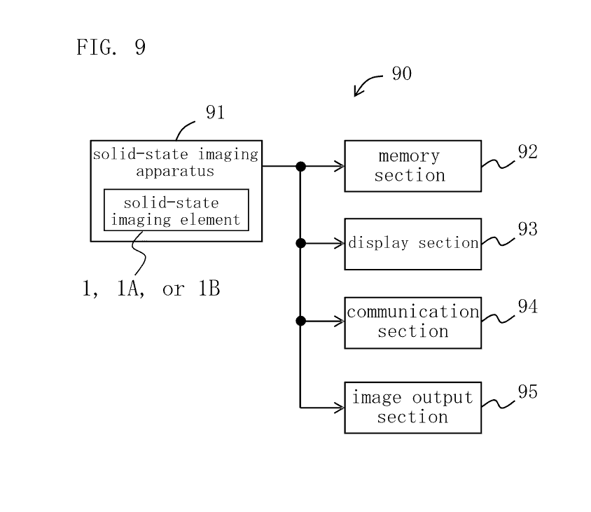

FIG. 9 is a block diagram showing, as Embodiment 4 of the present invention, an example of a schematic configuration of an electronic information device using the solid-state imaging element 1, 1A, or 1B of Embodiments 1 to 3 of the present invention for an imaging section.

In FIG. 9, an electronic information device 90 of Embodiment 3 comprises: a solid-state imaging apparatus 91 which obtains color image signals after performing predetermined signal processing on imaging signals from the solid-state imaging element 1, LA, or 1B of Embodiment 1 to 3 with the color filters of the present invention; a memory section 92 such as a storage media enabling data storage after performing predetermined signal processing on color image signals from the solid-state imaging apparatus 91 for storage; a display section 93 such as a liquid crystal display apparatus enabling display of an image on a display screen, such as a liquid crystal display screen, after performing predetermined signal processing on color image signals from the solid-state imaging apparatus 91 for display; a communication section 94, such as a transceiver, enabling communication operation after performing predetermined signal processing on color image signals from the solid-state imaging apparatus 91 for communication; and an image output section 95, such as a printer, enabling printing operation after performing predetermined printing signal processing on color image signals from the solid-state imaging apparatus 91 for printing. When the display section 93 is constituted of a liquid crystal display apparatus, color filters of the present invention may be used as the color filters of the liquid crystal display apparatus.

The electronic information device 90 is not limited to this configuration, and may only have, aside from the solid-state imaging apparatus 91, at least one of the memory section 92, the display section 93, the communication section 94, and the image output section 95 such as a printer.

As the electronic information device 90, an electronic device that includes an image input device is conceivable, such as a digital camera (e.g., digital video camera or digital still camera), an image input camera (e.g., a monitoring camera, an intercom camera, a camera equipped in a vehicle (e.g., a rear side monitoring camera equipped in a vehicle) or a camera for a videophone), a scanner, a facsimile machine, a camera-equipped cell phone device or a personal digital assistant (PDA).

Thus, according to Embodiment 4 of the present invention, color image signals from the solid-state imaging apparatus 91 can be: displayed on a display screen properly; printed out on a sheet of paper using the image output section 95 properly; communicated properly as communication data via a wire or a radio; and stored properly at the memory section 92 by performing a predetermined data compression processing, and various data processes can be properly performed.

In Embodiment 1 to 3, the color filters of the present invention have been described as being applied to the solid-state imaging element 1, 1A, or 1B, but they are not limited to such use. The color filters of the present invention can easily be used as color filters of a liquid crystal display apparatus.

In the liquid crystal display apparatus, liquid crystal is held between an element side substrate and an opposing side substrate, and an image is displayed according to the light transmittance of the liquid crystal for each pixel. Color filters of the present invention are formed on the opposing side substrate in such a manner to match each pixel.

As described above, the present invention is exemplified by the use of its preferred Embodiments 1 to 4. However, the present invention should not be interpreted solely based on Embodiments 1 to 4 described above. It is understood that the scope of the present invention should be interpreted solely based on the scope of the claims. It is also understood that those skilled in the art can implement equivalent scope of technology, based on the description of the present invention and common knowledge from the description of the detailed preferred Embodiments 1 to 4 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of: color filters in which the three primary colors RGB are arranged in a predetermined color arrangement; a solid-state imaging element for photo-electrically converting, and capturing an image of, an image light from a subject using the color filters; a liquid crystal display apparatus for displaying an image using the color filters; and an electronic information device, such as a digital camera (e.g., a digital video camera or a digital still camera), an image input camera (e.g., a monitoring camera), a scanner, a facsimile machine, a videophone device, and a camera-equipped cell phone device, using the solid-state imaging apparatus in a imaging section as an image input device, and/or using the liquid crystal display apparatus as a display section. Also, color filters are formed by adding a yellow to a green of a Bayer color arrangement as a new green, thereby improvement of color reproduction can be realized at low cost without complicating manufacturing steps of color filters. According to the present invention, color noise is reduced and color reproduction is improved without changing color signal processing of a device in such a manner to match a new color arrangement, when the spectral characteristic of green (G) of a green (G) color layer has a y-axis value greater than or equal to 0.45 and less than or equal to 0.60 on a CIE chromaticity diagram, by making the film thickness of a green in a Bayer color arrangement thinner and newly adding a thin yellow thereon.

1-24. (canceled)

25. Color filters of the three primary colors comprising a red (R) color layer, a green (G) color layer, and a blue (B) color layer in a predetermined color arrangement in a plane view, wherein a spectral characteristic of green (G) of the green (G) color layer has a y-axis value greater than or equal to 0.45 and less than or equal to 0.60 on a CIE chromaticity diagram.

26. Color filters according to claim 25, wherein the transmittance to an optical wavelength at the spectral characteristic of green (G) of the green (G) color layer is greater than 0 percent and less than or equal to 20 percent at an optical wavelength of 450 nm.

27. Color filters according to claim 25, wherein the transmittance to an optical wavelength at the spectral characteristic of green (G) of the green (G) color layer is greater than 0 percent and less than or equal to 10 percent at an optical wavelength of 450 nm.

28. Color filters according to claim 25, wherein the transmittance to an optical wavelength at the spectral characteristic of green (G) of the green (G) color layer is greater than or equal to 60 percent and less than or equal to 98 percent at an optical wavelength of 500 nm.

29. Color filters according to claim 25, wherein the transmittance to an optical wavelength at the spectral characteristic of green (G) of the green (G) color layer is greater than or equal to 60 percent and less than or equal to 90 percent at an optical wavelength of 500 nm.

30. Color filters according to claim 25, wherein the transmittance to an optical wavelength at the spectral characteristic of green (G) of the green (G) color layer is greater than 0 percent and less than or equal to 30 percent at an optical wavelength of 650 nm.

31. Color filters according to claim 25, wherein the transmittance to an optical wavelength at the spectral characteristic of green (G) of the green (G) color layer is greater than 0 percent and less than or equal to 20 percent at an optical wavelength of 650 nm.

32. Color filters according to claim 25, wherein the green (G) color layer is a two-layer configuration of a green (G1) color layer having a steeply inclined spectral characteristic with a high range of transmissivity extended towards the short wavelength and a yellow (Y1) color layer.

33. Color filters according to claim 32, wherein layer thicknesses of the green (G1) color layer and the yellow (Y1) color layer are thinner compared to layer thicknesses of the red (R) color layer and the blue (B) color layer excluding the green (G) color layer.

34. Color filters according to claim 33, wherein the layer thickness of the two-layer configuration of the green (G1) color layer and the yellow (Y1) color layer is substantially the same as the layer thicknesses of the red (R) color layer or the blue (B) color layer excluding the green (G) color layer.

35. Color filters according to claim 34, wherein the layer thickness of the green (G1) color layer and the layer thickness of the yellow (Y1) color layer are substantially the same.

36. Color filters according to claim 25, wherein the green (G) color layer is divided into two regions in the plane view; one of the divided regions is constituted of a green (G2) color layer having a steeply inclined spectral characteristic with a high range of transmissivity extended towards the short wavelength; and the other one of the divided regions is constituted of a yellow (Y2) color layer.

37. Color filters according to claim 36, wherein areas of respective regions of the green (G2) color layer and the yellow (Y2) color layer are substantially the same.

38. Color filters according to claim 36, wherein the arrangement of the green (G2) color layer and the yellow (Y2) color layer is such that the green (G2) color layer and the yellow (Y2) color layer are arranged in an alternating order for each minimum repeating adjacent four-pixel unit in a Bayer color arrangement.

39. Color filters according to claim 25, wherein green (G) color material and yellow (Y) color material are mixed into clear base material, thereby giving the green (G) color layer a steeply inclined spectral characteristic with a high range of transmissivity extended towards the short wavelength.

40. Color filters according to claim 25, wherein green (G) color material and yellow (Y) color material are mixed into clear base material, thereby giving the green (G) color layer a steeply inclined spectral characteristic with a high range of transmissivity extended towards the short wavelength and layer thickness substantially the same as the layer thickness of the red (R) color layer or the blue (B) color layer excluding the green (G) color layer.

41. Color filters according to claim 25, wherein the predetermined color arrangement is a Bayer color arrangement.

42. Color filters according to claim 25, wherein at least one of the green (G) color layer, the green (G1) color layer, and the green (G2) color layer has a steeply inclined spectral characteristic with a high range of transmissivity extended towards the short wavelength in comparison to a conventional green (G) color layer.

43. Color filters according to claim 25, wherein the ratio of the area in which the spectral characteristic of green (G) overlaps with the spectral characteristic of blue (B) is 23 percent±10 percent, and the ratio of the area in which the spectral characteristic of green (G) overlaps with the spectral characteristic of red (R) is 18 percent±5 percent.

44. A solid-state imaging element with a plurality of light reception sections arranged in a two dimensional pattern for photo-electrically converting, and capturing an image of, an image light from a subject, wherein color filters according to claim 25 are formed in such a manner as to match each of the plurality of light reception sections for respective colors.

45. A solid-state imaging element according to claim 44, wherein the solid-state imaging element is a CCD solid-state imaging element or a CMOS solid-state imaging element.

46. A liquid crystal display apparatus in which liquid crystal is held between an element side substrate and an opposing side substrate, and an image is displayed according to the light transmittance of liquid crystal for each pixel, wherein color filters according to claim 25 are formed on the opposing side substrate in such a manner to match each pixel for each color.

47. An electronic information device using the solid-state imaging element according to claim 44 in an imaging section as an image input device.

48. An electronic information device using the liquid crystal display apparatus according to claim 46 in a display section.
